(19) United States
(12) Patent Application Publication
(10) Pub. No.: US 2025/0336742 A1
(43) Pub. Date: Oct. 30, 2025

(54) SEMICONDUCTOR PACKAGE

(71) Applicant: SAMSUNG ELECTRONICS CO., LTD., Suwon-si (KR)

(72) Inventors: Jing Cheng Lin, Suwon-si (KR); Youngkun Jee, Suwon-si (KR)

(73) Assignee: SAMSUNG ELECTRONICS CO., LTD., Suwon-si (KR)

(21) Appl. No.: 19/089,928

(22) Filed: Mar. 25, 2025

(30) Foreign Application Priority Data
Apr. 24, 2024 (KR) 10-2024-0054990

(51) Int. Cl. H01L 23/31; H01L 23/00; H01L 23/48; H01L 23/538; H01L 25/16; H10B 80/00

(52) U.S. Cl. CPC H01L 23/3135; H01L 23/5384; H01L 24/08; H01L 25/16; H01L 23/481; H01L 2224/08145; H01L 2224/08225; H10B 80/00

(57) ABSTRACT

A semiconductor package includes: a base structure; a first semiconductor chip on an upper surface of the base structure and directly bonded to the base structure; a second semiconductor chip on the first semiconductor chip; a lower sealing layer on the upper surface of the base structure and on a sidewall of the first semiconductor chip; and a molding layer on an upper surface of the lower sealing layer and on a sidewall of the second semiconductor chip.

### CROSS-REFERENCE TO RELATED APPLICATION

This application is based on and claims priority under 35 USC § 119 to Korean Patent Application No. 10-2024-0054990, filed on Apr. 24, 2024, in the Korean Intellectual Property Office, the disclosure of which is incorporated by reference herein in its entirety.

### BACKGROUND

### 1. Field

Embodiments of the present disclosure relate to a semiconductor package and, more particularly, to a semiconductor package including stacked semiconductor chips.

### 2. Brief Description of Background Art

Semiconductor packages include integrated circuit chips implemented in a form suitable for use in electronic products. Generally, semiconductor packages are formed by mounting semiconductor chips on a printed circuit board and electrically connecting the semiconductor chips using bonding wires or bumps. With the development of the electronics industry, semiconductor packages may be required to implement high capacity characteristics. In addition, as electronic products have become smaller, demand for smaller semiconductor packages has increased.

### SUMMARY

According to embodiments of the present disclosure, a high-specification semiconductor package is provided.

According to embodiments of the present disclosure, a miniaturized semiconductor package is provided.

According to embodiments of the present disclosure, a semiconductor package is provided and includes: a base structure; a first semiconductor chip on an upper surface of the base structure and directly bonded to the base structure; a second semiconductor chip on the first semiconductor chip; a lower sealing layer on the upper surface of the base structure and on a sidewall of the first semiconductor chip; and a molding layer on an upper surface of the lower sealing layer and on a sidewall of the second semiconductor chip.

According to embodiments of the present disclosure, a semiconductor package is provided and includes: a base structure; a first semiconductor chip on an upper surface of the base structure and including a first substrate, a first through-via, and a first upper pad; a lower sealing layer on the upper surface of the base structure and on a sidewall of the first semiconductor chip; and an insulating layer on the first substrate and on a side surface of the first upper pad, wherein the insulating layer extends to an upper surface of the lower sealing layer.

According to embodiments of the present disclosure, a semiconductor package is provided and includes: a base structure including a base substrate, a conductive via within the base substrate, a base insulating layer on the base substrate, and a conductive pad within the base insulating layer; a redistribution layer on a lower surface of the base structure; a solder ball terminal on a lower surface of the redistribution layer and electrically connected to the conductive via through the redistribution layer; a first semiconductor chip on an upper surface of the base structure and including a first substrate, a first lower insulating layer on a lower surface of the first substrate, a first lower pad within the first lower insulating layer, a first through-via passing through the first substrate, and a first upper pad electrically connected to the first through-via; a plurality of second semiconductor chips stacked on the first semiconductor chip, each of the plurality of second semiconductor chips including a second substrate, a second lower insulating layer, a second lower pad, a second through-via, a second upper insulating layer, and a second upper pad; a lower sealing layer on the upper surface of the base structure and on a sidewall of the first semiconductor chip; a molding layer on the lower sealing layer and on sidewalls of the plurality of second semiconductor chips; and an insulating layer between the lower sealing layer and the molding layer and between the first semiconductor chip and a lowermost second semiconductor chip among the plurality of second semiconductor chips, wherein the insulating layer is on a side surface of the second lower pad of the lowermost second semiconductor chip, and wherein the first semiconductor chip is directly bonded to the base structure.

### BRIEF DESCRIPTION OF DRAWINGS

Embodiments will be more clearly understood from the following detailed description taken in conjunction with the accompanying drawings in which:

FIG. 1A is a cross-sectional view illustrating a semiconductor package according to embodiments;

FIG. 1B is an enlarged view of region I of the semiconductor package of FIG. 1A;

FIG. 1C is an enlarged view of region II of the semiconductor package of FIG. 1A;

FIG. 1D is an enlarged view of region III of the semiconductor package of FIG. 1A;

FIG. 1E is an enlarged view of region IV of the semiconductor package of FIG. 1A;

FIG. 2 is a cross-sectional view illustrating a semiconductor package according to embodiments;

FIG. 3 is a cross-sectional view illustrating a semiconductor package according to embodiments;

FIG. 4 is a cross-sectional view illustrating a semiconductor package according to embodiments;

FIGS. 5A to 5P are diagrams illustrating a manufacturing process of a semiconductor package according to embodiments; and

FIG. 6 is a diagram illustrating a semiconductor package according to embodiments.

### DETAILED DESCRIPTION

In this specification, like reference numerals may refer to like elements throughout. A semiconductor package and a manufacturing method thereof according to embodiments are described.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

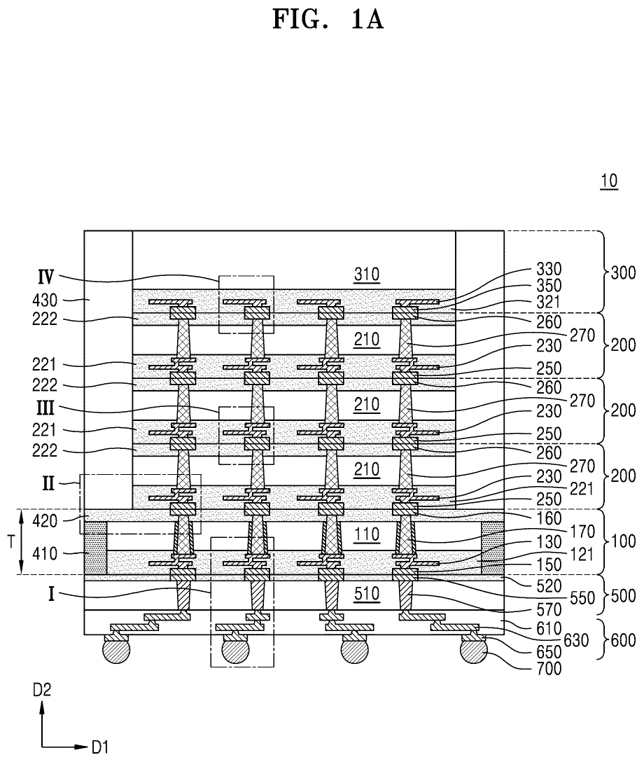

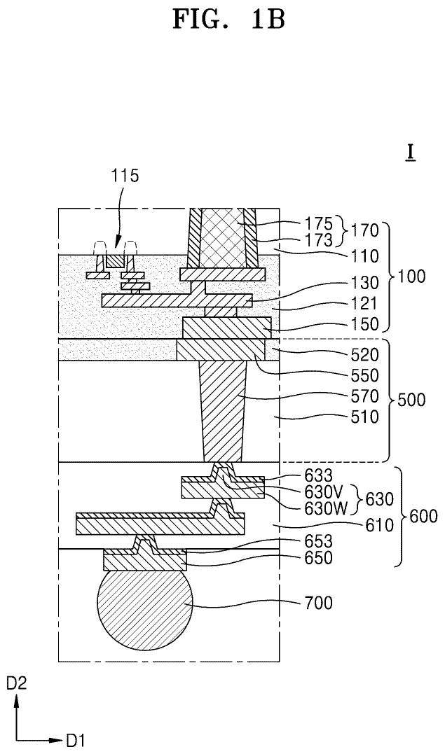

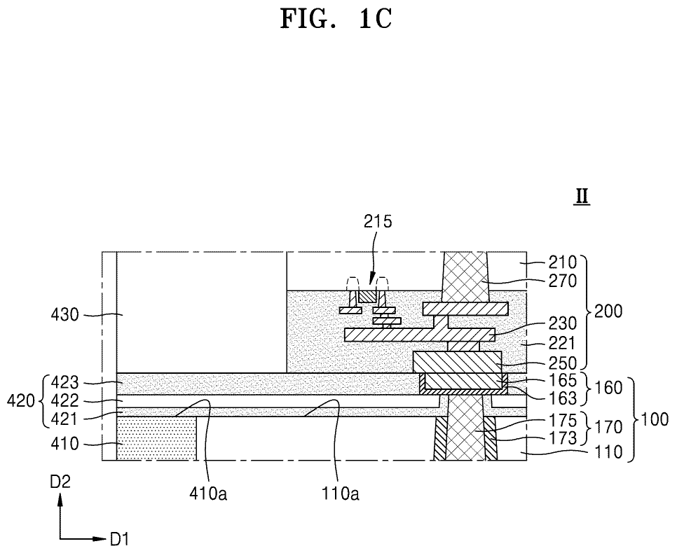

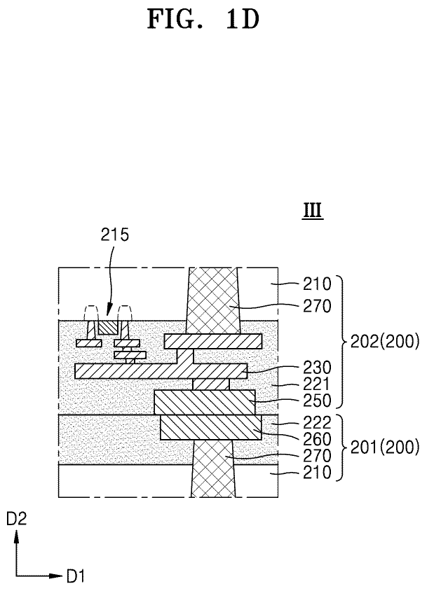

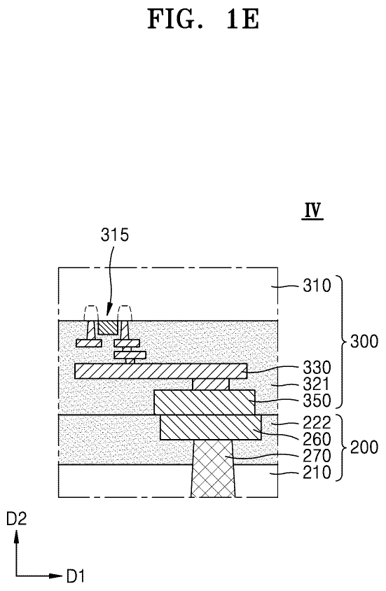

FIG. 1A is a cross-sectional view illustrating a semiconductor package 10 according to embodiments.

Referring to FIG. 1A, the semiconductor package 10 may include a memory package, such as a high bandwidth memory (HBM) package. The semiconductor package 10 may be a chip stack package. The semiconductor package 10 may include a redistribution layer 600, a base structure 500, a first semiconductor chip 100, second semiconductor chips 200, a third semiconductor chip 300, solder ball terminals 700, a lower sealing layer 410, an insulating layer 420, and a molding layer 430.

The base structure 500 may include a base substrate 510, a conductive via 570, a conductive pad 550, and a base insulating layer 520. The base substrate 510 may be manufactured using a semiconductor wafer. The base structure 500 may not include integrated circuits and transistors. The first semiconductor chip 100, the second semiconductor chips 200, and the third semiconductor chip 300 may be electrically connected to the redistribution layer 600 and the solder ball terminals 700 through the base structure 500. Being electrically connected to the base structure 500 may include being electrically connected to the conductive via 570 and the conductive pad 550. As used herein, being electrically connected includes a direct connection or an indirect connection through another conductive component. According to embodiments, the base structure 500 may further include a passive element therein. The passive element may include a capacitor, an inductor, or a resistor.

A first direction D1 may be parallel to a lower surface of the base substrate 510. A second direction D2 may intersect the lower surface of the base substrate 510. For example, the second direction D2 may be perpendicular to the lower surface of the base substrate 510. The second direction D2 may be a vertical direction.

The redistribution layer 600 may be disposed on the lower surface of the base substrate 510. The redistribution layer 600 may include an organic insulating layer 610, redistribution patterns 630, and redistribution pads 650. Electrically connecting to the redistribution layer 600 may include electrically connecting to the redistribution patterns 630. The redistribution patterns 630 may be electrically connected to corresponding ones of the conductive vias 570, respectively. The redistribution pads 650 may be disposed on a lower surface of the redistribution layer 600. The redistribution pads 650 may be electrically connected to the redistribution patterns 630. The redistribution pads 650 may be laterally apart from each other. Being laterally spaced may include being spaced horizontally. “Horizontal” may refer to a direction that is parallel to the lower surface of the base substrate 510.

The solder ball terminals 700 may be disposed on the lower surface of the redistribution layer 600. For example, the solder ball terminals 700 may be disposed on the lower surface of the redistribution pads 650 and connected to the redistribution pads 650. The solder ball terminals 700 may be electrically connected to the corresponding ones of the conductive vias 570, respectively, through the redistribution layer 600. For example, the solder ball terminals 700 may be electrically connected to the first semiconductor chip 100, the second semiconductor chips 200, and the third semiconductor chip 300 through the redistribution patterns 630 and the base structure 500. The solder ball terminals 700 may include a solder material. The solder material may include tin (Sn), silver (Ag), zinc (Zn), and/or alloys thereof.

The first semiconductor chip 100 may be disposed on an upper surface of the base structure 500. The first semiconductor chip 100 may be a lower semiconductor chip. The first semiconductor chip 100 may be a logic chip. A plurality of second semiconductor chips 200 may be provided on the first semiconductor chip 100. The second semiconductor chips 200 may be vertically stacked on an upper surface of the first semiconductor chip 100. Unless otherwise specified herein, “vertical” may refer to a direction that is parallel to the second direction D2. The second semiconductor chips 200 may be intermediate semiconductor chips. The third semiconductor chip 300 may be disposed on the uppermost one of the second semiconductor chips 200. For example, the second semiconductor chips 200 may be located between the third semiconductor chip 300 and the first semiconductor chip 100. The third semiconductor chip 300 may be an upper semiconductor chip. Two adjacent chips among the first semiconductor chip 100, the second semiconductor chips 200, and the third semiconductor chip 300 may be directly bonded to each other.

The second semiconductor chips 200 may be a same type of semiconductor chip as each other. Each of the second semiconductor chips 200 may be a memory chip, such as a dynamic random access memory (DRAM) chip. For example, each of the second semiconductor chips 200 may be a high bandwidth memory (HBM) chip. A storage capacity of each of the second semiconductor chips 200 may be the same. The second semiconductor chips 200 may have the same size. For example, each of the second semiconductor chips 200 may have substantially the same width and thickness as each other. The width of any component may be measured in the first direction D1. The thickness of any component may be measured in the second direction D2. The sameness of the widths, thicknesses, sizes, levels, and widths of certain components may refer to the sameness of an error range that may occur during the process. Sidewalls of the second semiconductor chips 200 may be vertically aligned with each other.

The third semiconductor chip 300 may be the same type of semiconductor chip as the second semiconductor chips 200. The third semiconductor chip 300 may be a memory chip, such as a DRAM chip. For example, the third semiconductor chip 300 may be an HBM chip. A storage capacity of the third semiconductor chip 300 may be the same as the storage capacity of each of the second semiconductor chips 200. The width of the third semiconductor chip 300 may be substantially the same as the width of each of the second semiconductor chips 200. A sidewall of the third semiconductor chip 300 may be vertically aligned with the sidewalls of the second semiconductor chips 200. However, a thickness of the third semiconductor chip 300 may be greater than the thickness of each of the second semiconductor chips 200.

The first semiconductor chip 100 may be a different type of semiconductor chip from the second semiconductor chips 200 and the third semiconductor chip 300. A width of the first semiconductor chip 100 may be different from the widths of the second semiconductor chips 200 and the width of the third semiconductor chip 300. For example, the width of the first semiconductor chip 100 may be greater than the widths of the second semiconductor chips 200 and the width of the third semiconductor chip 300. A thickness T of the first semiconductor chip 100 may be about 7 μm to about 60 μm. Accordingly, the semiconductor package 10 may be miniaturized. The thickness T of the first semiconductor chip 100 may correspond to a gap between the lower surface of the first semiconductor chip 100 and an upper surface of the first upper pads 160.

The number of second semiconductor chips 200 is not limited to the number shown in FIG. 1A and may vary in various manners. For example, the semiconductor package 10 may include a single second semiconductor chip 200 or four or more second semiconductor chips 200. In contrast, the semiconductor package 10 may not include the second semiconductor chip 200. In this case, the third semiconductor chip 300 may be disposed directly on the first semiconductor chip 100.

The lower sealing layer 410 may be disposed on the upper surface of the base structure 500 and cover the sidewall of the first semiconductor chip 100. The lower sealing layer 410 may be an insulating layer. As an example, the lower sealing layer 410 may include a silicon-containing insulating material, such as silicon oxide. As another example, the lower sealing layer 410 may include an insulating polymer, such as benzocyclobutene (BCB) and/or polyimide.

The molding layer 430 may be provided on the lower sealing layer 410 to cover the sidewalls of the second semiconductor chips 200 and the sidewall of the third semiconductor chip 300. An upper surface of the molding layer 430 may be coplanar with an upper surface of the third semiconductor chip 300. The molding layer 430 may be apart from the lower sealing layer 410. As an example, the molding layer 430 may include an insulating material different from an insulating material of the lower sealing layer 410. For example, the molding layer 430 may include an insulating polymer, such as epoxy molding compound (EMC).

The insulating layer 420 may be provided between the first semiconductor chip 100 and the lowermost one of the second semiconductor chips 200 and may extend between the lower sealing layer 410 and the molding layer 430. The insulating layer 420 may include a silicon-based insulating material. For example, the insulating layer 420 may include silicon oxide, silicon nitride, and/or combinations thereof.

An outer wall of the molding layer 430 may be vertically aligned (e.g., coplanar) with an outer wall of the insulating layer 420, an outer wall of the lower sealing layer 410, an outer wall of the base structure 500, and an outer wall of the redistribution layer 600.

FIG. 1B is an enlarged view of region I of the semiconductor package 10 of FIG. 1A. FIG. 1C is an enlarged view of region II of the semiconductor package 10 of FIG. 1A. FIG. 1D is an enlarged view of region III of the semiconductor package 10 of FIG. 1A. FIG. 1E is an enlarged view of region IV of the semiconductor package 10 of FIG. 1A. Hereinafter, the redistribution layer 600, the base structure 500, the first semiconductor chip 100, the second semiconductor chips 200, the third semiconductor chip 300, and the insulating layer 420 are described in more detail.

Referring to FIG. 1B together with FIG. 1A, the base structure 500 may include a base substrate 510, a conductive via 570, a conductive pad 550, and a base insulating layer 520. The base substrate 510 may be a semiconductor substrate. The semiconductor substrate may include a semiconductor material, such as silicon, germanium, or silicon-germanium.

The conductive vias 570 may be provided within the base substrate 510. For example, the conductive via 570 may penetrate the top and lower surfaces of the base substrate 510. The conductive via 570 may include a metal material, such as copper, tungsten, titanium, and/or combinations thereof. The conductive pad 550 may be provided on the conductive via 570 and electrically connected to the conductive via 570. The conductive pad 550 may include a metal, such as copper.

The base insulating layer 520 may be provided on an upper surface of the base substrate 510 to cover side surfaces of the conductive pad 550. The base insulating layer 520 may include, for example, silicon oxide, silicon carbonitride, and/or combinations thereof. An upper surface of the base structure 500 may include an upper surface of the base insulating layer 520 and an upper surface of the conductive pad 550.

The redistribution layer 600 may include a plurality of organic insulating layers 610, redistribution patterns 630, and redistribution pads 650. The organic insulating layers 610 may be vertically stacked. The number of stacked organic insulating layers 610 may vary. For example, the organic insulating layers 610 may include the same material as each other. An interface between adjacent ones of the organic insulating layers 610 may not be distinguished. The organic insulating layers 610 may include an organic material, such as a photo-imageable dielectric (PID) material. A photosensitive polymer may include, for example, at least one from among photosensitive polyimide (PSPI), polybenzoxazole, phenol-based polymer, and benzocyclobutene-based polymer. The uppermost one of the organic insulating layers 610 may directly contact a lower surface of the base substrate 510.

The redistribution patterns 630 may be provided between the organic insulating layers 610 and extend into the organic insulating layers 610. Some of the redistribution patterns 630 may be vertically stacked and electrically connected to each other. The redistribution patterns 630 may include metal, such as copper and/or a copper alloy.

Each of the redistribution patterns 630 may include a via portion 630V and an interconnection portion 630W. The interconnection portion 630W of each of the redistribution patterns 630 may be provided between the organic insulating layers 610. The via portion 630V of each of the redistribution patterns 630 may be provided within the corresponding one of the organic insulating layer 610. The via portion 630V of each of the redistribution patterns 630 may be provided on a lower surface of the interconnection portion 630W and may be connected to the interconnection portion 630W without an interface. A width of the interconnection portion 630W of each of the redistribution patterns 630 may be greater than a width of the via portion 630V.

The redistribution layer 600 may further include seed patterns 633. The seed patterns 633 may be disposed on the upper surfaces of the redistribution patterns 630, respectively. For example, each of the seed patterns 633 may cover an upper surface and a sidewall of the via portion 630V and an upper surface of the interconnection portion 630W of the corresponding one of the redistribution patterns 630. The uppermost ones of the seed patterns 633 may be provided between the uppermost ones of the redistribution patterns 630 and the conductive vias 570. The uppermost ones of the seed patterns 633 may directly contact the conductive vias 570. The seed patterns 633 may include a material different from a material of the redistribution patterns 630. For example, the seed patterns 633 may include a conductive seed material. The conductive seed material may include titanium, copper, and/or alloys thereof. The seed patterns 633 may function as barrier layers to prevent diffusion of materials included in the redistribution patterns 630. The redistribution patterns 630 may be formed through a plating process using the seed patterns 633 as electrodes.

The redistribution pads 650 may be provided on a lower surface of the lowermost one of the organic insulating layers 610 and may extend further into the lowermost one of the organic insulating layers 610. A lower portion of each of the redistribution pads 650 may be disposed on a lower surface of the lowermost one of the organic insulating layers 610. An upper portion of each of the redistribution pads 650 may be disposed within the lowermost one of the organic insulating layers 610. A lower portion of each of the redistribution pads 650 has a width greater than a width of the upper portion thereof and may be connected to the upper portion thereof. The redistribution pads 650 may be electrically connected to the redistribution patterns 630.

The redistribution layer 600 may further include seed pads 653. The seed pads 653 may be provided on upper surfaces of the redistribution pads 650. The seed pads 653 may be provided between the lowermost ones of the redistribution patterns 630 and the redistribution pads 650 and may extend between the lowermost one of the organic insulating layers 610 and the redistribution pads 650. The seed pads 653 may include a metal material different from a metal material of the redistribution pads 650. The seed pads 653 may include, for example, a conductive seed material.

The first semiconductor chip 100 may be disposed on the base structure 500. The first semiconductor chip 100 may include a first semiconductor substrate 110, first integrated circuits 115, a first lower insulating layer 121, first lower pads 150, first interconnection patterns 130, first through-vias 170, and first upper pads 160 (see FIG. 1C). The first semiconductor substrate 110 may be a first substrate. The first semiconductor substrate 110 may include a semiconductor material, such as silicon, germanium, or silicon-germanium.

As shown in FIG. 1B, the first integrated circuits 115 may be provided on the lower surface of the first semiconductor substrate 110. The lower surface of the first semiconductor substrate 110 may be a frontside surface. The first integrated circuits 115 may include, for example, transistors. The first integrated circuits 115 may include logic circuits.

The first lower insulating layer 121 may be provided on the lower surface of the first semiconductor substrate 110 and may cover the first integrated circuits 115. The first lower insulating layer 121 may include a silicon-based insulating material. The silicon-based insulating material may include, for example, silicon oxide and/or silicon carbide nitride. The first lower insulating layer 121 may include a plurality of stacked layers.

The first interconnection patterns 130 may be provided in the first lower insulating layer 121. Each of the first interconnection patterns 130 may be electrically connected to at least one from among the first integrated circuits 115 and the first through-vias 170. That a component is electrically connected to a semiconductor chip may mean that it is electrically connected to at least one from among the through-vias and integrated circuits of the semiconductor chip.

The first lower pads 150 may be disposed at (e.g., on or in) the lower surface of the first semiconductor chip 100. For example, the first lower pads 150 may be disposed on a lower surface of the first semiconductor substrate 110 and within the first lower insulating layer 121. The first lower pads 150 may be electrically connected to the first integrated circuits 115 and the first through-vias 170 through the first interconnection patterns 130. The first lower pads 150 may include, for example, copper. The lower surface of the first semiconductor chip 100 may include lower surfaces of the first lower pads 150 and the lower surface of the first lower insulating layer 121.

Hereinafter, bonding between the base structure 500 and the first semiconductor chip 100 is described. Hereinafter, for simplicity, a single first lower pad 150 is described.

The first semiconductor chip 100 may be directly bonded to the base structure 500. Direct bonding may be formed by a hybrid bonding process. For example, the first lower pad 150 may be directly disposed on the conductive pad 550 and directly bonded to the conductive pad 550. During the hybrid bonding process, metal atoms in the first lower pad 150 may diffuse into the conductive pad 550, and metal atoms in the conductive pad 550 may diffuse into the first lower pad 150. Accordingly, the first lower pad 150 may be firmly coupled to the conductive pad 550. When direct bonding of the first semiconductor chip 100 and the base structure 500 is performed under conditions of a certain temperature or higher, the interface between the first lower pad 150 and the conductive pad 550 may not be distinguished. In this case, the interface between the first lower pad 150 and the conductive pad 550 in FIGS. 1A and 1B may be a virtual interface. In contrast, the interface between the first lower pad 150 and the conductive pad 550 may be distinguished depending on bonding process conditions. Because the first semiconductor chip 100 is directly bonded to the base structure 500, solder balls between the base structure 500 and the first semiconductor chip 100 may be omitted. Accordingly, the semiconductor package 10 may be miniaturized.

As shown in FIG. 1B, a side surface of at least one of a plurality of first lower pads 150 may not be vertically aligned (e.g., coplanar) with a side surface of the corresponding conductive pad 550. The side surface of one of the first lower pads 150 may be offset from the side surface of the conductive pad 550 in the first direction D1 or in a direction opposite to the first direction D1. According to embodiments, the side surface of the first lower pad 150 may be vertically aligned with the side surface of the conductive pad 550.

The first lower insulating layer 121 may directly contact the base insulating layer 520 and may be directly bonded to the base insulating layer 520. For example, a chemical bond may be provided between the first lower insulating layer 121 and the base insulating layer 520. The chemical bond may be a covalent bond. Accordingly, the first lower insulating layer 121 may be firmly coupled to the base insulating layer 520. The first lower insulating layer 121 and the base insulating layer 520 may include the same material as each other but are not limited thereto. For example, an interface between the first lower insulating layer 121 and the base insulating layer 520 may not be distinguished. Referring to FIGS. 1A and 1B, the interface between the first lower insulating layer 121 and the base insulating layer 520 may be a virtual interface. As another example, the interface between the first lower insulating layer 121 and the base insulating layer 520 may be distinguished.

The first through-vias 170 may be provided within the first semiconductor substrate 110 and may pass through the first semiconductor substrate 110. The first through-vias 170 may further pass through at least a portion of the first lower insulating layer 121. The first through-vias 170 may be laterally apart from each other. For example, the first through-vias 170 may be apart from each other in the first direction D1 or in a direction opposite to the first direction D1. The first through-vias 170 may be electrically connected to the first lower pads 150 and/or the first integrated circuits 115 through the first interconnection patterns 130.

Each of the first through-vias 170 may include a first conductive via 175 and a first barrier layer 173. The first conductive via 175 may include a metal, such as copper or tungsten. The first barrier layer 173 may be located between the first conductive via 175 and the first semiconductor substrate 110. The first barrier layer 173 may cover a sidewall of the first conductive via 175. The first barrier layer 173 may include a metal different from a metal of the first conductive via 175. The first barrier layer 173 may prevent the metal included in the first conductive via 175 from diffusing into the first semiconductor substrate 110. The first barrier layer 173 may include a barrier metal material. The barrier metal material may include at least one from among titanium (Ti), titanium nitride (TiN), tantalum (Ta), and tantalum nitride (TaN).

Referring to FIG. 1C together with FIG. 1A, the insulating layer 420 may be disposed on an upper surface 110a of the first semiconductor substrate 110. The upper surface 110a of the first semiconductor substrate 110 may face in a direction opposite of a facing direction of a lower surface of the first semiconductor substrate 110. The upper surface 110a of the first semiconductor substrate 110 may be a backside surface. The upper surface 110a of the first semiconductor substrate 110 may be coplanar with an upper surface 410a of the lower sealing layer 410. The insulating layer 420 may include silicon oxide, silicon nitride, and/or combinations thereof.

A first conductive via 175 may be further provided within the insulating layer 420. The first barrier layer 173 may not extend into the insulating layer 420. For example, the first barrier layer 173 may not be located between the first conductive via 175 and the insulating layer 420. The insulating layer 420 may extend to an upper surface of the first barrier layer 173 and cover upper sidewalls of the first conductive via 175.

The first upper pads 160 may be disposed on the upper surface 110a of the first semiconductor substrate 110. The first upper pads 160 may be provided on the first through-vias 170 and electrically connected to the first through-vias 170. For example, each of the first upper pads 160 may be provided on a corresponding one of the first conductive vias 175 and may be electrically connected to the first conductive vias 175. As an example, each of the first upper pads 160 may be apart from the corresponding one of the first barrier layers 173. Lower surfaces of the first upper pads 160 may be provided at a higher level than the uppermost surface of the first barrier layer 173. In this specification, the level of an element may refer to a vertical level.

The first upper pads 160 may be disposed within the insulating layer 420. The lower surfaces and side surfaces of the first upper pads 160 may be covered with the insulating layer 420. Upper surfaces of the first upper pads 160 may not be covered with the insulating layer 420. For example, the upper surfaces of the first upper pads 160 may be disposed at substantially the same level as a level of an upper surface of the insulating layer 420. The upper surfaces of the first upper pads 160 may be coplanar with the upper surface of the insulating layer 420.

Each of the first upper pads 160 may include a metal pad 165 and a barrier pad 163. The metal pad 165 may include the same metal as a metal of the first lower pads 150. For example, the metal pad 165 may include copper. The barrier pad 163 may cover the lower and side surfaces of the metal pad 165. The barrier pad 163 may include a different metal from a metal of the metal pad 165. For example, the barrier pad 163 may include a barrier metal material. Hereinafter, a single first upper pad 160 and a single first through-via 170 are described.

The insulating layer 420 may include multiple layers. For example, the insulating layer 420 may include a first layer 421, a second layer 422, and a third layer 423 that are stacked. The first layer 421 may be provided on the upper surface 110a of the first semiconductor substrate 110 and extend to upper sidewalls of the first through-vias 170. For example, the first layer 421 may cover the upper surface of the first barrier layer 173 and the upper sidewall of the first conductive via 175. The uppermost surface of the first layer 421 may physically contact a lower surface of the first upper pad 160. The first layer 421 may extend to the upper surface 410a of the lower sealing layer 410 and cover the upper surface 410a of the lower sealing layer 410. The first layer 421 may be located between the first conductive via 175 and the second layer 422, between the first semiconductor substrate 110 and the second layer 422, and between the lower sealing layer 410 and the second layer 422. The second layer 422 may be provided on the first layer 421. The second layer 422 may be located between the first layer 421 and the third layer 423. The third layer 423 may be provided on the first layer 421 and cover a side surface of the first upper pad 160.

The second layer 422 may include a material different from a material of the first layer 421 and the third layer 423. For example, the first layer 421 may include silicon oxide, the second layer 422 may include silicon nitride, and the third layer 423 may include silicon oxide. The number and materials of layers included in the insulating layer 420 may vary.

According to embodiment, the upper surface 110a of the first semiconductor substrate 110 may be a frontside surface, and a lower surface of the first semiconductor substrate 110 may be the backside surface. In this case, the first integrated circuits 115 and first interconnection patterns 130 may be disposed on the upper surface 110a of the first semiconductor substrate 110.

Each of the second semiconductor chips 200 may include a second semiconductor substrate 210, second integrated circuits 215, a second lower insulating layer 221, second lower pads 250, second interconnection patterns 230, second through-vias 270, second upper pads 260, and a second upper insulating layer 222. Unless otherwise specified, materials, arrangements, and the electrical connection relationship of the second semiconductor substrate 210, the second integrated circuits 215, the second lower insulating layer 221, the second interconnection patterns 230, and the second through-vias 270 may be substantially the same as materials, arrangements, and the electrical connection relationship of the first semiconductor substrate 110, the first integrated circuits 115, the first lower insulating layer 121, the first interconnection patterns 130, and the first through-vias 170. The second semiconductor substrate 210 may be a second substrate.

The second integrated circuits 215 may be provided on a lower surface of the second semiconductor substrate 210. The second integrated circuits 215 may be different types of circuits from types of the first integrated circuits 115. The second integrated circuits 215 may be memory circuits.

The second semiconductor substrate 210 may include a semiconductor material. The second lower insulating layer 221 may be provided on the lower surface of the second semiconductor substrate 210 and cover the second integrated circuits 215. According to embodiments, the second lower insulating layer 221 may include multiple layers. The second interconnection patterns 230 may be provided in the second lower insulating layer 221.

The second lower insulating layer 221 and the second lower pads 250 may be provided at (e.g., in or on) the lower surface of the second semiconductor chip 200. For example, the second lower insulating layer 221 and the second lower pads 250 may be disposed on the lower surface of the second semiconductor substrate 210. The second lower pads 250 may be disposed within the second lower insulating layer 221. The upper surfaces and side surfaces of the second lower pads 250 may be covered with the second lower insulating layer 221. The lower surfaces of the second lower pads 250 may be coplanar with the lower surface of the second lower insulating layer 221 and may be disposed at substantially the same level as that of the lower surface of the second lower insulating layer 221. The lower surface of the second semiconductor chip 200 may include the lower surfaces of the second lower pads 250 and the lower surface of the second lower insulating layer 221. The second lower pads 250 may be electrically connected to the second integrated circuits 215 and/or the second through-vias 270 through the second interconnection patterns 230. The second lower pads 250 may include the same metal as a metal of the metal pad 165. The second lower pads 250 may include, for example, copper. Hereinafter, for simplicity, a single second lower pad 250 and a single first upper pad 160 are described.

The lowermost one of the second semiconductor chips 200 may be directly bonded to the first semiconductor chip 100. Direct bonding of any two chips may be formed by a hybrid bonding process. Direct bonding of two chips may include directly bonding conductive components of the two chips facing each other and directly bonding insulating components of the two chips facing each other. Direct bonding of insulating components may include forming a chemical bond between the insulating components. For example, the second lower pad 250 may be provided directly on the first upper pad 160 and may be directly bonded to the first upper pad 160. During the hybrid bonding process, metal atoms in the second lower pad 250 may diffuse into the first upper pad 160, and metal atoms in the first upper pad 160 may diffuse into the second lower pad 250. Accordingly, the second lower pad 250 may be firmly coupled to the first upper pad 160. For example, an interface between the first upper pad 160 and the second lower pad 250 may not be distinguished. In this case, the interface between the first upper pad 160 and the second lower pad 250 in FIGS. 1A and 1C may be a virtual interface. As another example, the interface between the first upper pad 160 and the second lower pad 250 may be distinguished. As shown in FIG. 1C, a side surface of at least one from among a plurality of second lower pads 250 may not be vertically aligned (e.g., coplanar) with a side surface of the corresponding first upper pad 160. The side surface of one of the second lower pads 250 may be offset from the side surface of the first upper pad 160 in the first direction D1 or in a direction opposite to the first direction D1. According to embodiments, the side surface of the second lower pad 250 may be vertically aligned with the side surface of the first upper pad 160.

The second lower insulating layer 221 of the lowermost one of the second semiconductor chips 200 may be in direct contact with the insulating layer 420 and may be connected by direct bonding. For example, the second lower insulating layer 221 of the lowermost one of the second semiconductor chips 200 may include the same insulating material as the insulating material of the insulating layer 420. A chemical bond may be provided between the second lower insulating layer 221 of the lowermost one of the second semiconductor chips 200 and the third layer 423 of the insulating layer 420. The chemical bond may be a covalent bond. Accordingly, the lowermost one of the second semiconductor chips 200 may be firmly coupled to the first semiconductor chip 100. For example, an interface between the second lower insulating layer 221 of the lowermost one of the second semiconductor chips 200 and the third layer 423 may not be distinguished. In this case, the interface between the third layer 423 and the second lower insulating layer 221 of the lowermost one of the second semiconductor chips 200 in FIG. 1C may be a virtual interface. As another example, the interface between the third layer 423 and the second lower insulating layer 221 of the lowermost one of the second semiconductor chips 200 may be distinguished.

The second through-vias 270 may be provided within the second semiconductor substrate 210 and may pass through the second semiconductor substrate 210. The second through-vias 270 may further pass through at least a portion of the second lower insulating layer 221 and be electrically connected to the second interconnection patterns 230. According to embodiments, each of the second through-vias 270 may include a second conductive via and a second barrier layer. The second barrier layer may be located between the second conductive via and the second semiconductor substrate 210. The second barrier layer may include a different metal from a metal of the second conductive via.

Referring to FIG. 1D together with FIG. 1A, the second upper insulating layer 222 may be disposed on the upper surface of the second semiconductor substrate 210. The upper surface of the second semiconductor substrate 210 may be a backside surface. The second upper insulating layer 222 may include a silicon-based insulating material and may include multiple layers. For example, the second upper insulating layer 222 may include silicon oxide, silicon carbide nitride, and/or combinations thereof.

The second through-vias 270 may protrude from an upper surface of the second semiconductor substrate 210. The second through-vias 270 may extend further into the second upper insulating layer 222.

The second upper pads 260 may be provided on the second through-vias 270 and electrically connected to the second through-vias 270. The second upper pads 260 may be disposed within the second upper insulating layer 222. For example, the lower surfaces and side surfaces of the second upper pads 260 may be covered with the second upper insulating layer 222. Upper surfaces of the second upper pads 260 may not be covered with the second upper insulating layer 222. For example, the upper surfaces of the second upper pads 260 may be disposed at substantially the same level as that of the second upper insulating layer 222 and may be coplanar with the second upper insulating layer 222. The second upper pads 260 may include the same metal as that of the second lower pads 250. The second upper pads 260 may include, for example, copper.

Hereinafter, bonding between the second semiconductor chips 200 is described. For simplicity, a single second upper pad 260 and a single second lower pad 250 are described.

The second semiconductor chips 200 may be directly bonded to each other. For example, adjacent ones of the second semiconductor chips 200 may include a second lower semiconductor chip 201 and a second upper semiconductor chip 202 as shown in FIG. 1D. The second upper semiconductor chip 202 may be disposed directly on the second lower semiconductor chip 201 and directly bonded to the second lower semiconductor chip 201. For example, the second upper pad 260 of the second lower semiconductor chip 201 and the second lower pad 250 of the second upper semiconductor chip 202 may be in direct contact with each other and directly bonded to each other. An interface between the second upper pad 260 of the second lower semiconductor chip 201 and the second lower pad 250 of the second upper semiconductor chip 202 may not be distinguished. The interface between the second upper pad 260 of the second lower semiconductor chip 201 and the second lower pad 250 of the second upper semiconductor chip 202 may be a virtual interface. As another example, the interface between the second upper pad 260 of the second lower semiconductor chip 201 and the second lower pad 250 of the second upper semiconductor chip 202 may be distinguished.

A side surface of at least one from among a plurality of second upper pads 260 may not be vertically aligned (e.g., coplanar) with a side surface of the corresponding one of the second lower pads 250. The side surface of one of the second upper pads 260 may be offset from the side surface of the second lower pad 250 in the first direction D1 or in a direction opposite to the first direction D1. According to embodiments, the side surface of the second upper pad 260 may be vertically aligned with the side surface of the second lower pad 250.

The second lower insulating layer 221 of the second upper semiconductor chip 202 may be in direct contact with the second upper insulating layer 222 of the second lower semiconductor chip 201 and may be connected to the second upper insulating layer 222 by direct bonding. For example, the second lower insulating layer 221 of the second upper semiconductor chip 202 may include the same insulating material as an insulating material of the second upper insulating layer 222 of the second lower semiconductor chip 201. A chemical bond may be provided between the second lower insulating layer 221 of the second upper semiconductor chip 202 and the second upper insulating layer 222 of the second lower semiconductor chip 201. The chemical bond may be a covalent bond. For example, an interface between the second lower insulating layer 221 of the second upper semiconductor chip 202 and the second upper insulating layer 222 of the second lower semiconductor chip 201 may not be distinguished. The interface between the second upper insulating layer 222 and the second lower insulating layer 221 that contact each other may be a virtual interface. In contrast, the interface between the second upper insulating layer 222 and the second lower insulating layer 221 that contact each other may be distinguished.

Referring to FIG. 1E together with FIG. 1A, the third semiconductor chip 300 may include a third semiconductor substrate 310, third integrated circuits 315, a third lower insulating layer 321, third lower pads 350, and third interconnection patterns 330. Materials, arrangements, and an electrical connection relationship of the third semiconductor substrate 310, the third integrated circuits 315, the third lower insulating layer 321, the third lower pads 350, and the third interconnection patterns 330 may be substantially the same as materials, arrangements, and an electrical connection relationship of the second semiconductor substrate 210, the second integrated circuits 215, the second lower insulating layer 221, and the second interconnection patterns 230, respectively.

The third integrated circuits 315 may be provided on the lower surface of the third semiconductor substrate 310. The third integrated circuits 315 may include, for example, transistors. The third integrated circuits 315 may be memory circuits and may be the same type of circuits as the second integrated circuits 215 (see FIG. 1C).

The third lower insulating layer 321 may be provided on the lower surface of the third semiconductor substrate 310. The third lower insulating layer 321 may include silicon oxide, silicon carbide nitride, and/or combinations thereof. According to embodiments, the third lower insulating layer 321 may include multiple layers. Third interconnection patterns 330 may be provided within the third lower insulating layer 321 and electrically connected to the third integrated circuits 315.

The third lower pads 350 may be provided at (e.g., in or on) a lower surface of the third semiconductor chip 300. For example, the third lower pads 350 may be disposed on the lower surface of the third semiconductor substrate 310 and within the third lower insulating layer 321. Upper surfaces and side surfaces of the third lower pads 350 may be covered with the third lower insulating layer 321. Lower surfaces of the third lower pads 350 may be coplanar with the lower surfaces of the third lower insulating layer 321. The third lower pads 350 may be electrically connected to the third integrated circuits 315 through the third interconnection patterns 330. However, the third lower pads 350 may include the same metal as a material of the second upper pads 260. The third lower pads 350 may include, for example, copper. A lower surface of the third semiconductor chip 300 may include lower surfaces of the third lower pads 350 and a lower surface of the third lower insulating layer 321.

Hereinafter, bonding between the uppermost one of the second semiconductor chips 200 and the third semiconductor chip 300 is described. Hereinafter, for simplicity, a single second upper pad 260 and a single third lower pad 350 are described.

The third semiconductor chip 300 may be directly bonded to the uppermost one of the second semiconductor chips 200. For example, the third lower pad 350 of the third semiconductor chip 300 and the second upper pad 260 of the uppermost one of the second semiconductor chips 200 may be in direct contact with each other and directly bonded to each other. For example, an interface between the second upper pad 260 and the third lower pad 350 may not be distinguished. In this case, the interface between the second upper pad 260 and the third lower pad 350 that contact each other in FIGS. 1A and 1E may be a virtual interface. As another example, the interface between the second upper pad 260 and the third lower pad 350 may be distinguished. As shown in FIG. 1C, a side surface of at least one of a plurality of third lower pads 350 may not be vertically aligned (e.g., coplanar) with a side surface of the corresponding one of the second upper pads 260. The side surface of the at least one third lower pad 350 may be offset from the side surface of the second upper pad 260 in the first direction D1 or in a direction opposite to the first direction D1. According to embodiments, the side surface of the third lower pad 350 may be vertically aligned with the side surface of the second upper pad 260.

The third lower insulating layer 321 may be in direct contact with the second upper insulating layer 222 of the uppermost one of the second semiconductor chips 200 and may be connected to the second upper insulating layer 222 through direct bonding. For example, the third lower insulating layer 321 may include the same insulating material as an insulating material of the second upper insulating layer 222 of the uppermost one of the second semiconductor chips 200. A chemical bond may be provided between the second upper insulating layer 222 of the uppermost one of the second semiconductor chips 200 and the third lower insulating layer 321. The chemical bond may be a covalent bond. An interface between the second upper insulating layer 222 and the third lower insulating layer 321 may not be distinguished. In this case, the interface between the second upper insulating layer 222 of the uppermost one of the second semiconductor chips 200 and the third lower insulating layer 321 in FIGS. 1A and 1E may be a virtual interface. As another example, the interface between the second upper insulating layer 222 and the third lower insulating layer 321 may be distinguished.

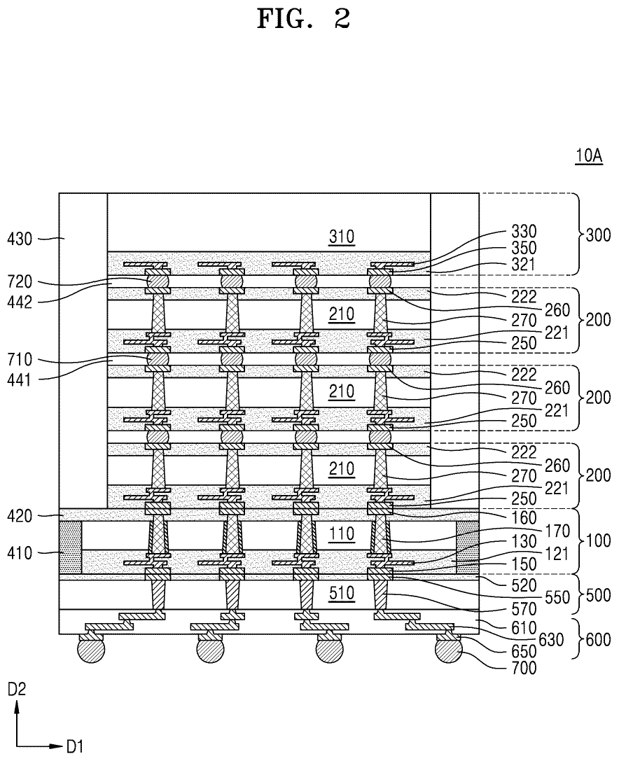

FIG. 2 is a cross-sectional view illustrating a semiconductor package 10A according to embodiments. Hereinafter, the same descriptions as those given above may be omitted.

Referring to FIG. 2, the semiconductor package 10A may be a memory package, such as an HBM package. The semiconductor package 10A may be a chip stack package. The semiconductor package 10A may include first solder bumps 710 and second solder bumps 720 in addition to the redistribution layer 600, the base structure 500, the first semiconductor chip 100, the second semiconductor chips 200, the third semiconductor chip 300, the solder ball terminals 700, the lower sealing layer 410, the insulating layer 420, and the molding layer 430.

The first solder bumps 710 may be provided between the second semiconductor chips 200 and electrically connected to the second semiconductor chips 200. The lowermost one of the second semiconductors chip 200 may not be directly bonded to the first semiconductor chip 100. For example, the first solder bumps 710 may be located between the second upper pads 260 and the second lower pads 250 facing each other and may be electrically connected to the second upper pads 260 and the second lower pads 250 facing each other. The first solder bumps 710 may include a solder material.

The semiconductor package 10A may further include first insulating films 441. Each of the first insulating films 441 may be provided between adjacent ones of the second semiconductor chips 200 and cover sidewalls of the first solder bumps 710. The first insulating films 441 may include a non-conductive film (NCF). The first insulating films 441 may include an insulating polymer.

The second solder bumps 720 may be provided between the uppermost one of the second semiconductor chips 200 and the third semiconductor chip 300 and may be electrically connected to the uppermost one of the second semiconductor chip 200 and the third semiconductor chip 300. The third semiconductor chip 300 may not be directly bonded to the uppermost one of the second semiconductor chips 200. For example, the second solder bumps 720 may be located between the second upper pads 260 and third lower pads 350 facing each other. The second solder bumps 720 may be electrically connected to the second upper pads 260 and third lower pads 350 facing each other. The second solder bumps 720 may include a solder material.

The semiconductor package 10A may further include a second insulating film 442. The second insulating film 442 may be provided between the uppermost one of the second semiconductor chips 200 and the third semiconductor chip 300 and cover the sidewalls of the second solder bumps 720. For example, the second insulating film 442 may include a non-conductive film.

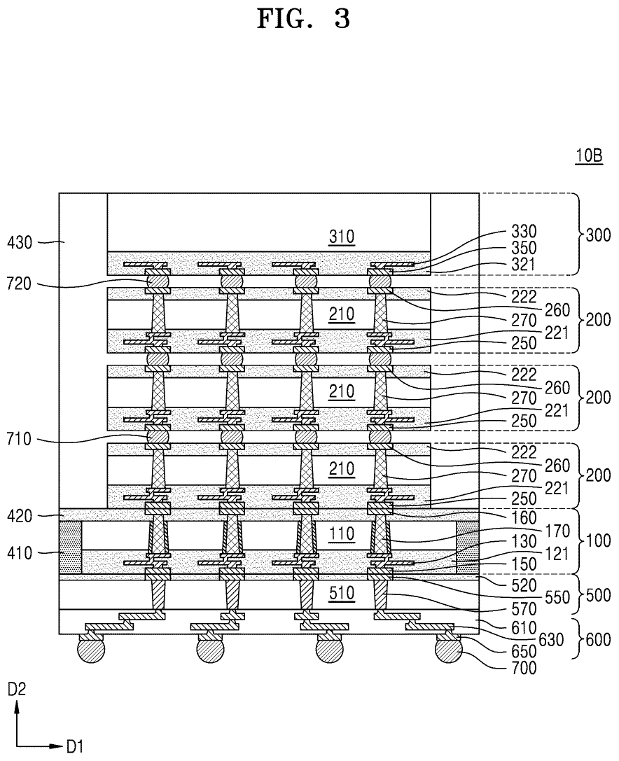

FIG. 3 is a cross-sectional view illustrating a semiconductor package 10B according to embodiments.

Referring to FIG. 3, the semiconductor package 10B may be a memory package, such as an HBM package. The semiconductor package 10B may be a chip stack package. The semiconductor package 10B may include the first solder bumps 710 and the second solder bumps 720 in addition to the redistribution layer 600, the base structure 500, the first semiconductor chip 100, the second semiconductor chips 200, the third semiconductor chip 300, the solder ball terminals 700, the lower sealing layer 410, the insulating layer 420, and the molding layer 430. The first solder bumps 710 and the second solder bumps 720 may be substantially the same as those described above in the example of FIG. 2. The semiconductor package 10B may not include the first insulating films 441 and the second insulating films 442 of FIG. 2.

The molding layer 430 may be provided on the upper surface of the insulating layer 420 and cover the sidewalls of the second semiconductor chips 200 and the third semiconductor chip 300. The molding layer 430 may have a molded underfill structure. For example, the molding layer 430 may extend between the second semiconductor chips 200 and seal the first solder bumps 710. The molding layer 430 may further extend between the third semiconductor chip 300 and the uppermost one of the second semiconductor chips 200 and seal the second solder bumps 720.

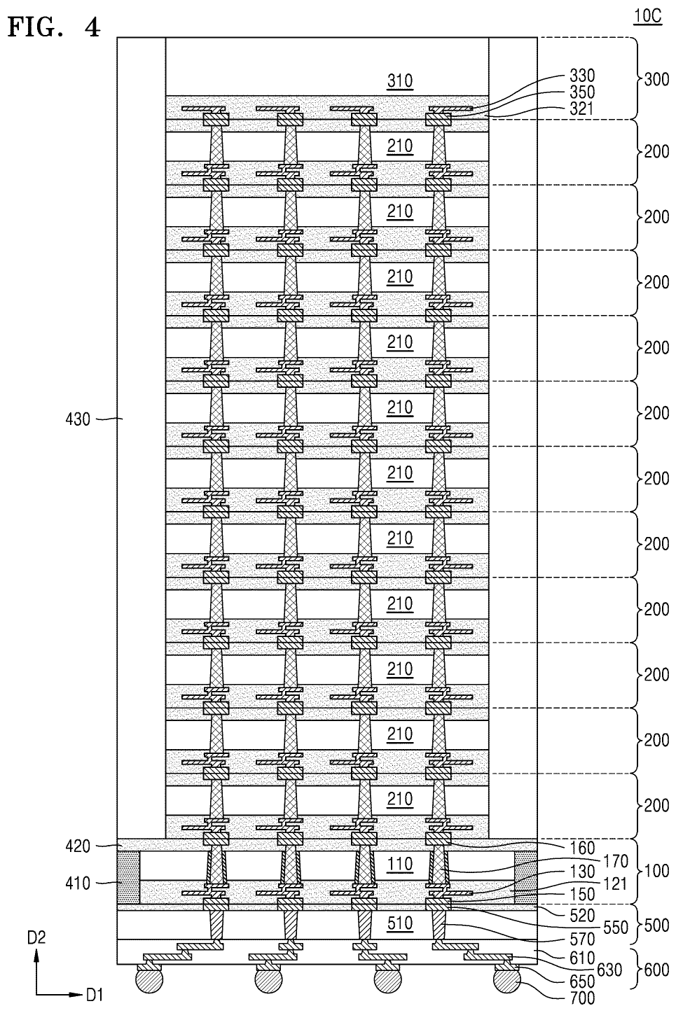

FIG. 4 is a cross-sectional view illustrating a semiconductor package 10C according to embodiments.

Referring to FIG. 4, the semiconductor package 10C may include the redistribution layer 600, the base structure 500, the first semiconductor chip 100, the second semiconductor chips 200, the third semiconductor chip 300, the solder ball terminals 700, the lower sealing layer 410, the insulating layer 420, and the molding layer 430. The semiconductor package 10C may include 11 second semiconductor chips 200. The number of stacked second semiconductor chips 200 may vary. For example, the semiconductor package 10C may include 19 or more second semiconductor chips 200.

At least two of the embodiments may be combined with each other. For example, the semiconductor package 10C of FIG. 4 may further include the first solder bumps 710 and the second solder bumps 720 like the semiconductor package 10A of FIG. 2. However, embodiments are not limited thereto and may be combined in various manners.

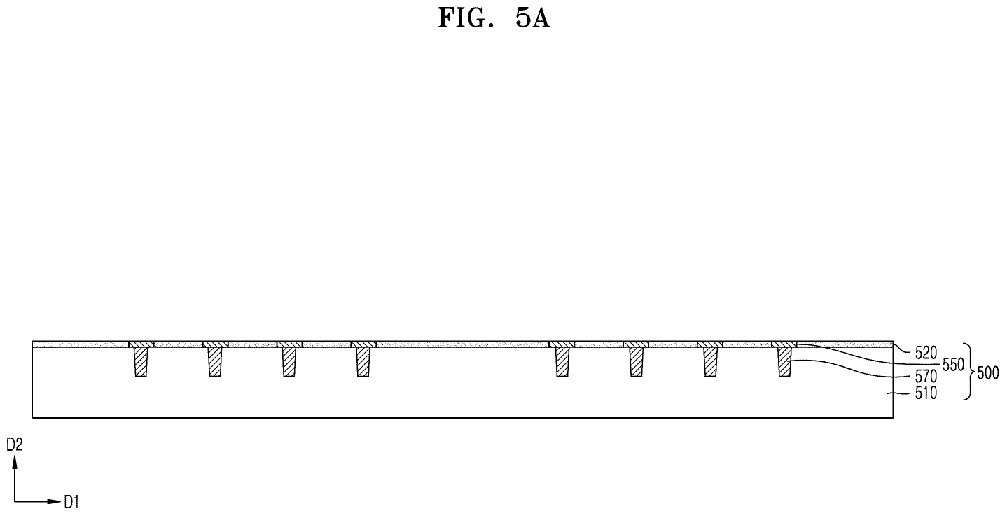

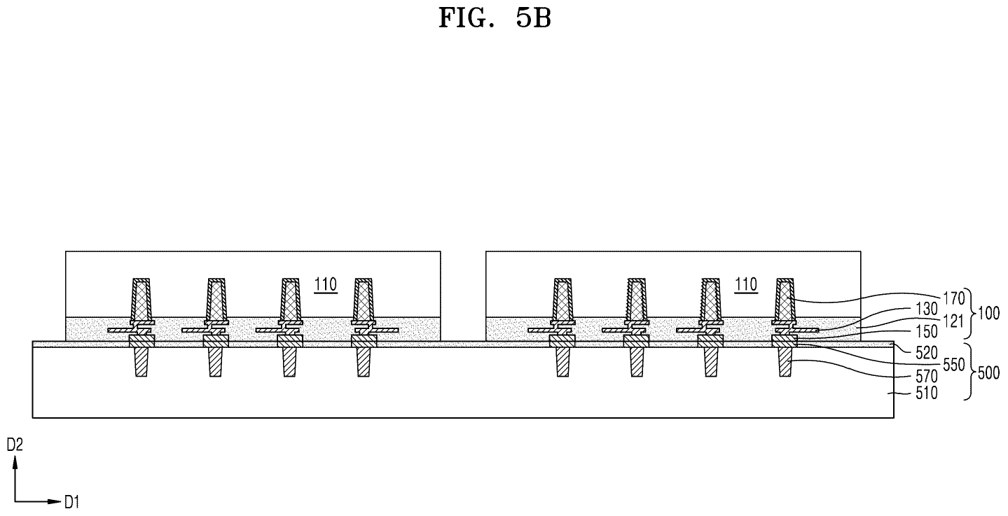

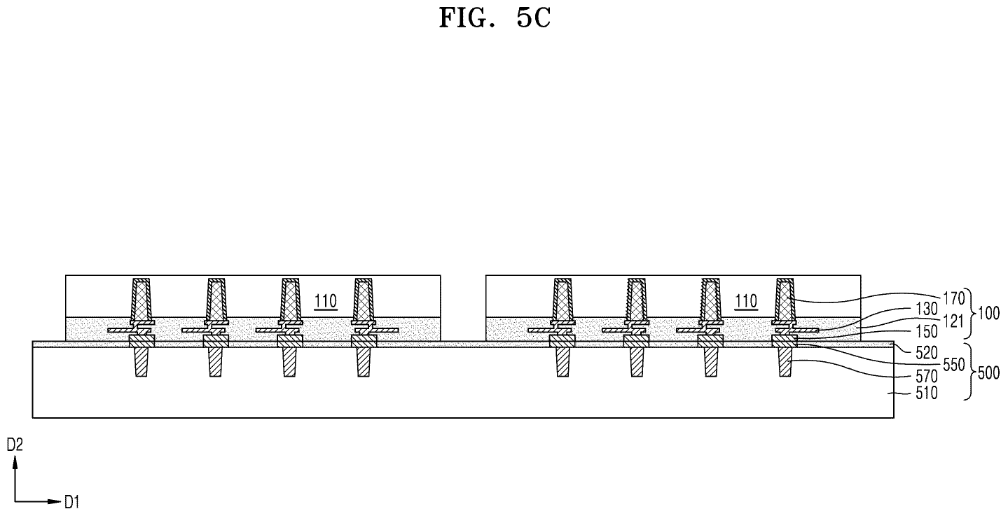

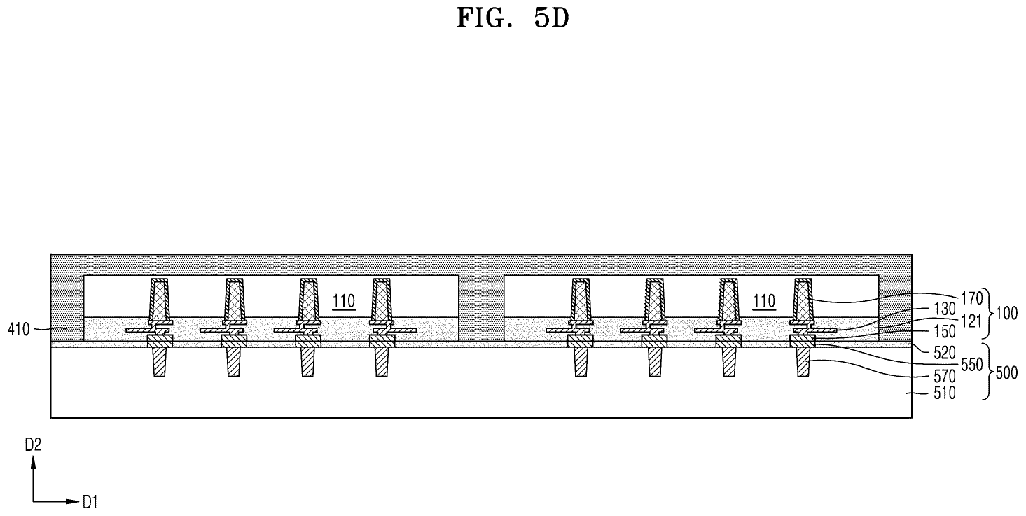

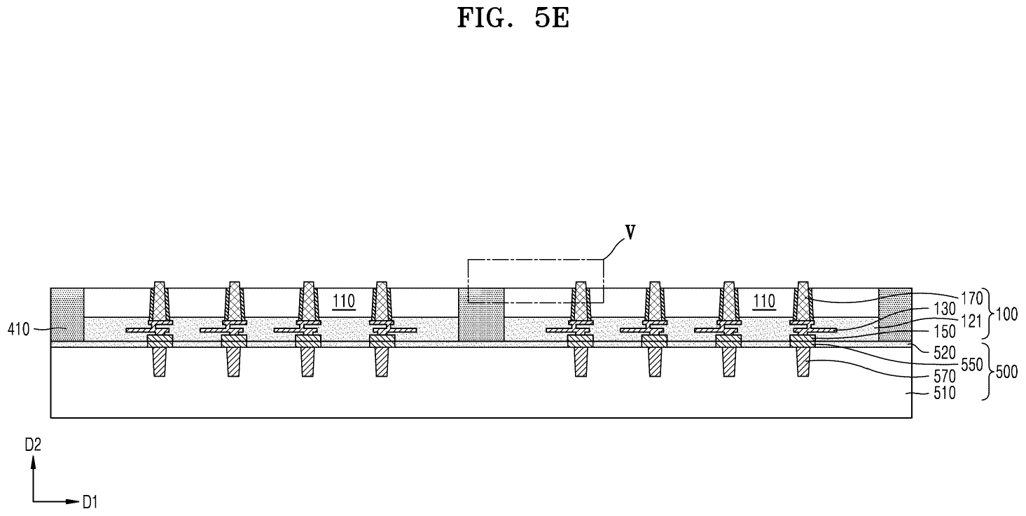

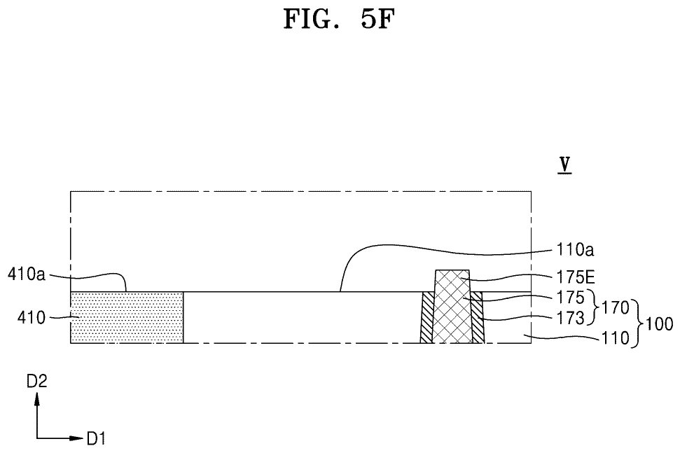

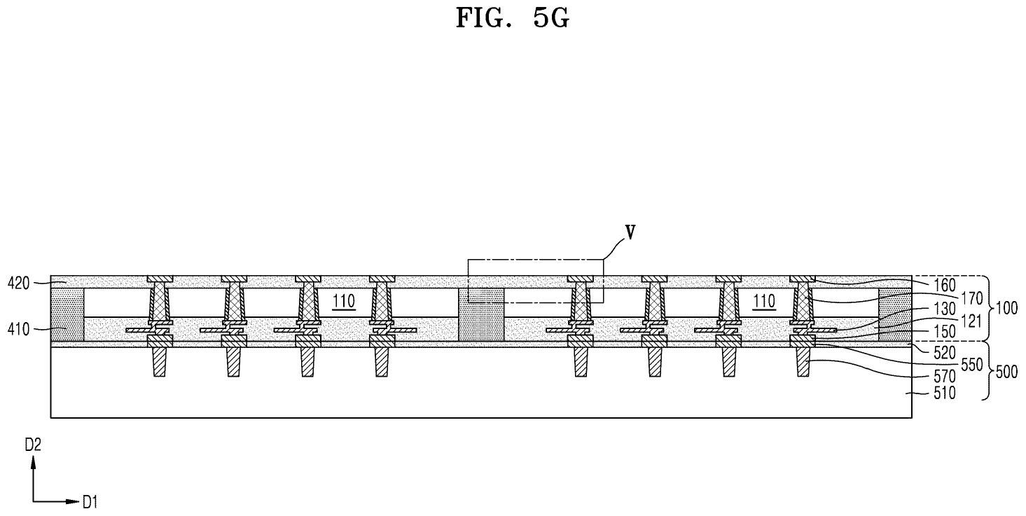

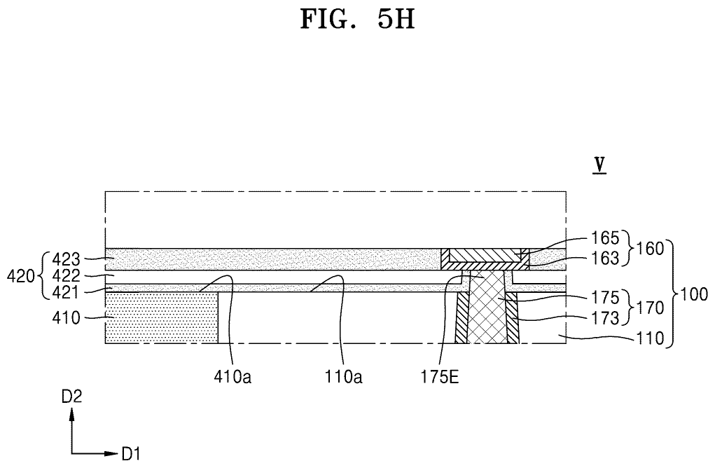

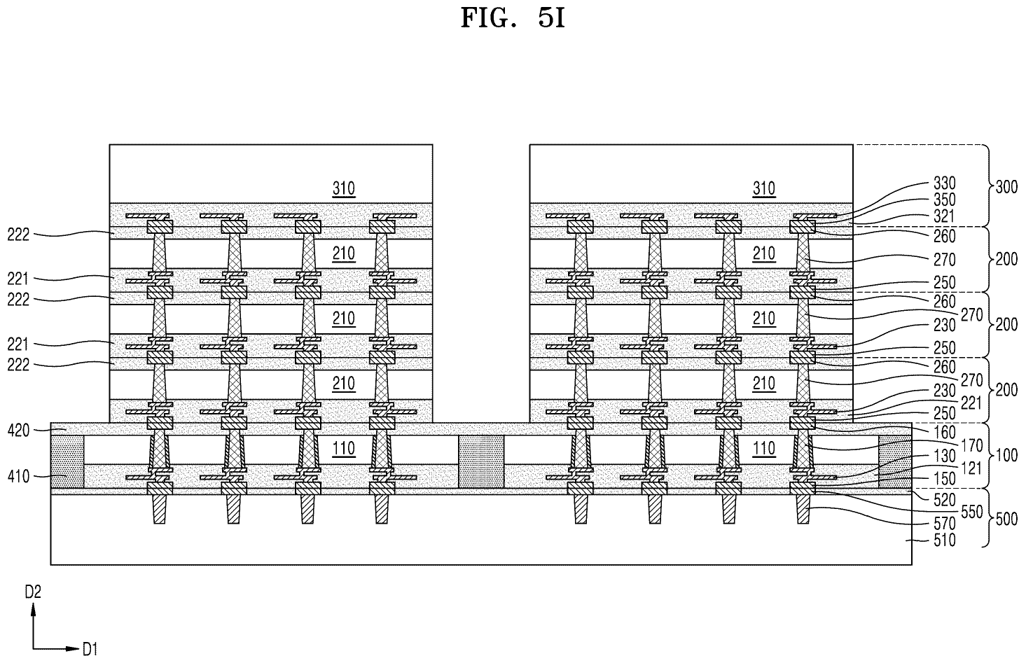

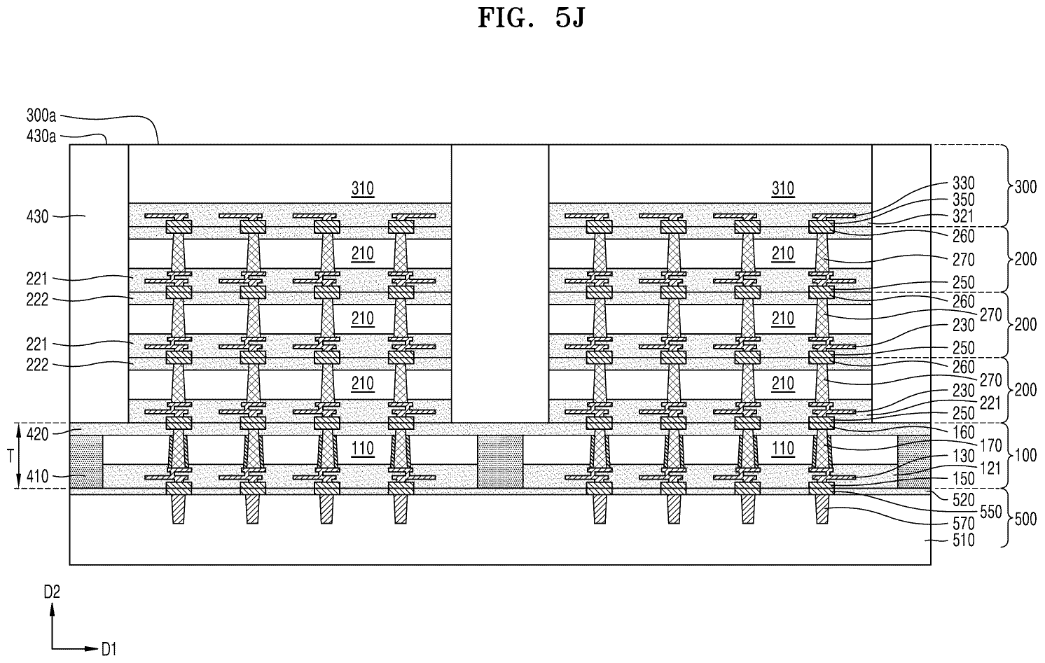

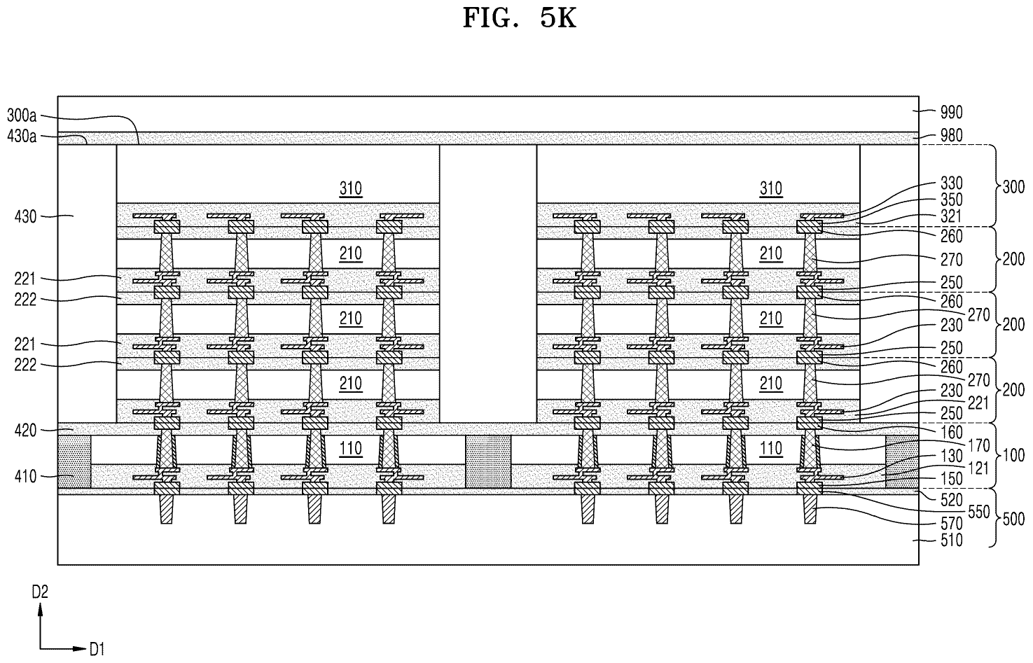

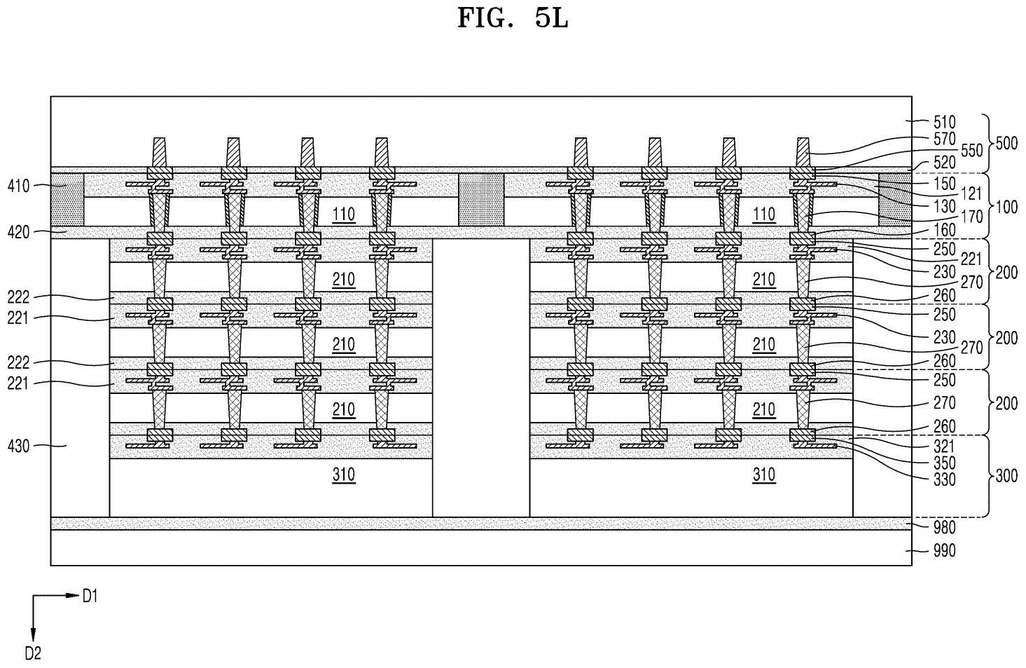

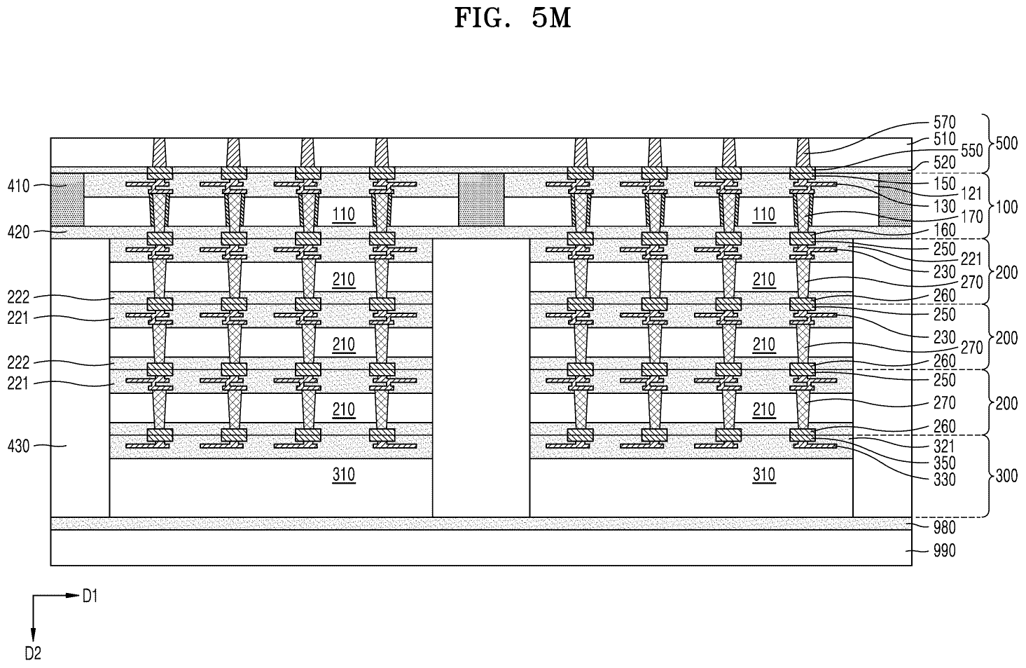

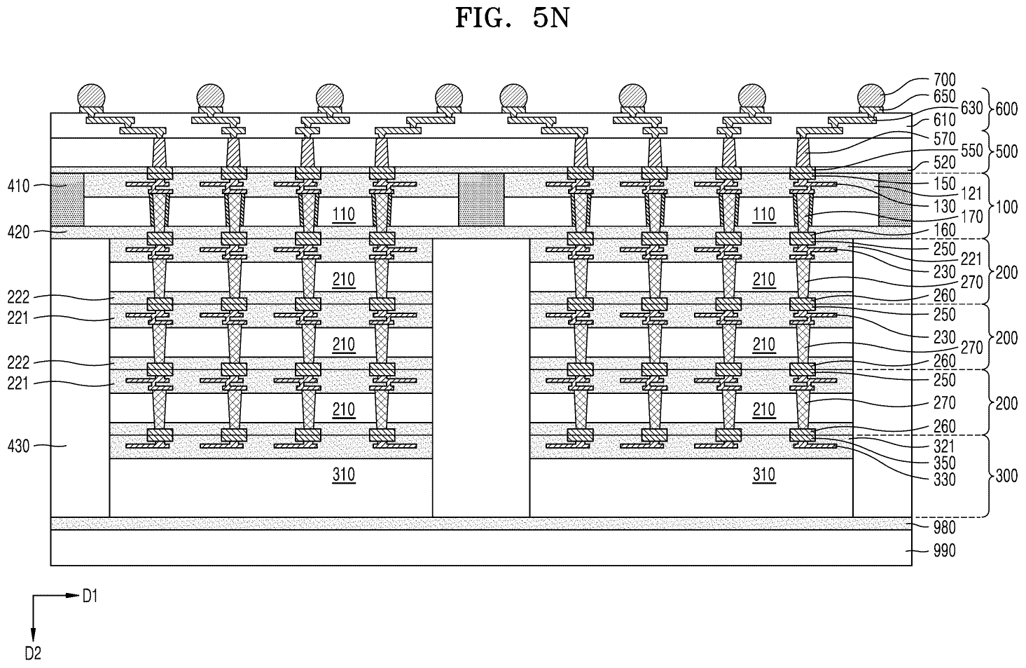

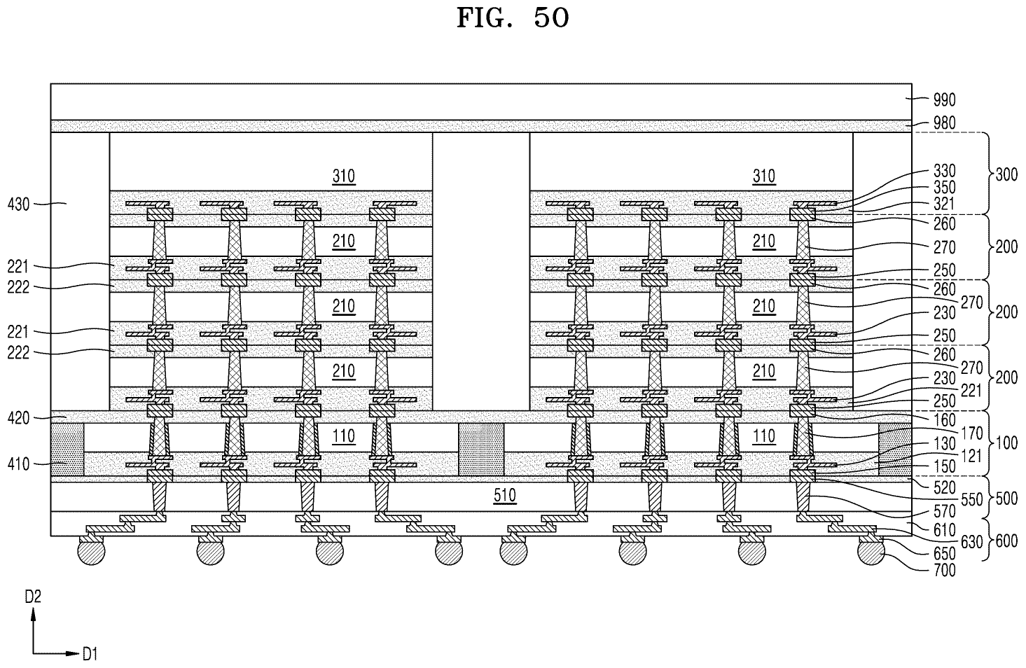

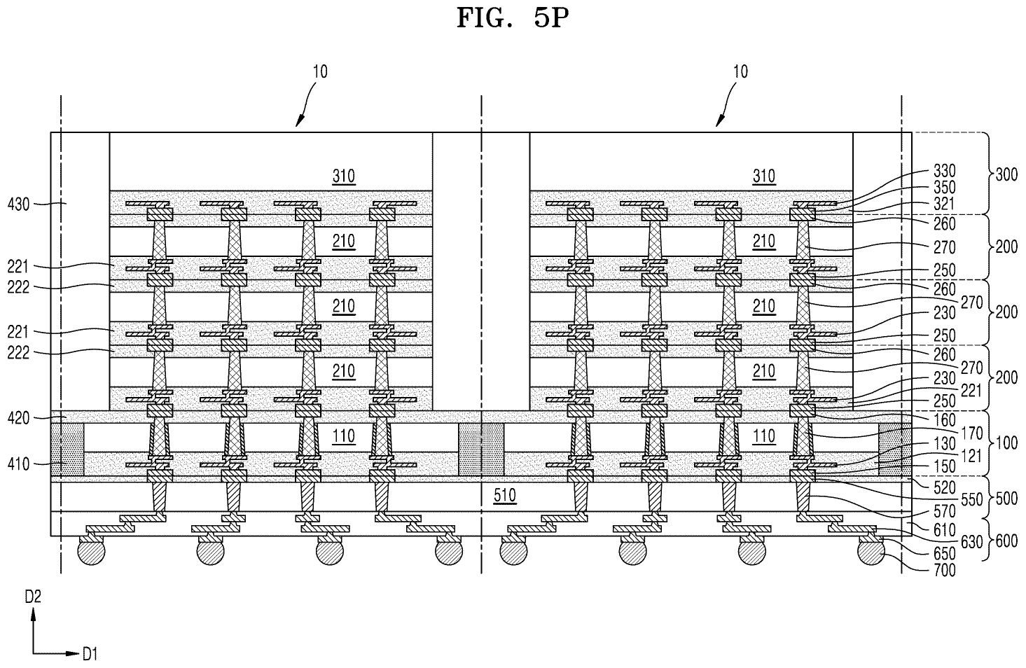

FIGS. 5A to 5P are diagrams illustrating a manufacturing process of a semiconductor package according to embodiments. Hereinafter, the same descriptions as those given above may be omitted. In the following descriptions of FIGS. 5A to 5P, an upper surface, a lower surface, an upper portion, and a lower portion are described based on FIGS. 5A and 5P for uniformity of description.

Referring to FIG. 5A, the base structure 500 may be prepared. The base structure 500 may be the same as or similar to that of the examples of FIGS. 1A and 1B. However, the base structure 500 may be prepared at a wafer level. For example, the base structure 500 may include a plurality of base units. Each of the plurality of base units may include the base substrate 510, the conductive via 570, the conductive pad 550, and the base insulating layer 520. The conductive via 570 may pass through the upper surface of the base substrate 510 and may be apart from the lower surface of the base substrate 510. For example, the lower surface of the conductive via 570 may be provided in the base substrate 510.

A testing process for the base structure 500 may be performed. The base structure 500 that has passed the test process may be used to manufacture a semiconductor package.

Referring to FIG. 5B, a plurality of first semiconductor chips 100 may be prepared. Each of the first semiconductor chips 100 may include the first semiconductor substrate 110, the first integrated circuits 115 (see FIG. 1B), the first lower insulating layer 121, the first lower pads 150, the first interconnection patterns 130, and first through-vias 170. However, the first through-vias 170 may pass through the lower surface of the first semiconductor substrate 110 but may not pass through the upper surface of the first semiconductor substrate 110. The upper surfaces of the first through-vias 170 may be provided within the first semiconductor substrate 110. For example, the upper surfaces of the first through-vias 170 may be provided at a lower level than a level of the upper surface of the first semiconductor substrate 110. Each of the first semiconductor chips 100 may not include the first upper pads 160 described above in the examples of FIGS. 1A and 1B.

The first semiconductor chips 100 may be provided on the upper surface of the base substrate 510. For example, the first semiconductor chips 100 may be directly disposed on the upper surface of the base substrate 510. The first semiconductor chips 100 may be arranged to be laterally apart from each other. Here, the lower surfaces of the first lower pads 150 may be in direct contact with the upper surfaces of the conductive pads 550, and the lower surface of the first lower insulating layer 121 may be in direct contact with the upper surface of the base insulating layer 520.

The first semiconductor chips 100 may be directly bonded to the base substrate 510 through a hybrid bonding process. Performing the hybrid bonding process may include performing a heat treatment process on the base substrate 510 and the first semiconductor chips 100. Performing the hybrid bonding process may further include, but is not limited to, performing a plasma treatment process on the upper surface of the base substrate 510 and the lower surfaces of the first semiconductor chips 100 before the heat treatment process. During the heat treatment process, additional pressure may be applied to the base substrate 510 and the first semiconductor chips 100, but is not limited thereto.

When the first semiconductor chips 100 are bonded at the wafer level, it may be difficult to selectively exclude first semiconductor chips 100 that are defective from the semiconductor package manufacturing process. According to embodiments, the first semiconductor chips 100 may be provided at a chip level. For example, the first semiconductor chips 100 may be separately provided on the base structure 500. Before the bonding process of the first semiconductor chips 100, a test process of the first semiconductor chips 100 may be performed. According to embodiments, each of the first semiconductor chips 100 may be a semiconductor chip that has passed a test. Accordingly, first semiconductor chips 100 that are defective may not be used in manufacturing a semiconductor package. The first semiconductor chips 100, which has good quality, may be used to manufacture a semiconductor package. Similarly, the base structure 500, which has good quality, may be used in the bonding process. Accordingly, the efficiency of the manufacturing process of the semiconductor package may be improved. The yield of the manufacturing process of the semiconductor package may be improved.

Referring to FIG. 5C, a thinning process may be performed on the first semiconductor chips 100 to reduce a thickness of the first semiconductor chips 100. The thinning process may include a grinding after bonding (GAB) process. After the thinning process, the upper surfaces of the first through-vias 170 may be provided within the first semiconductor substrate 110. Through the thinning process, a distance between the upper surfaces of the first through-vias 170 and the upper surface of the first semiconductor substrate 110 may be reduced.

Referring to FIG. 5D, the lower sealing layer 410 may be formed on the base substrate 510 and cover the first semiconductor chips 100. The lower sealing layer 410 may cover the upper surface of the base insulating layer 520, the sidewalls of the first semiconductor chips 100, and the upper surfaces of the first semiconductor chips 100. The lower sealing layer 410 may fill gaps between the first semiconductor chips 100. The upper surface of the lower sealing layer 410 may be provided at a higher level than a level of the upper surfaces of the first semiconductor chips 100. When the lower sealing layer 410 includes a silicon-containing insulating material, forming the lower sealing layer 410 may be performed by a deposition process, such as chemical vapor deposition. When the lower sealing layer 410 includes an insulating polymer, forming the lower sealing layer 410 may be performed by coating fixation.

Referring to FIGS. 5E and 5F, wherein FIG. 5F is an enlarged view of a region V of FIG. 5E, a grinding process may be performed on the lower sealing layer 410 to expose the end portions of the first through-vias 170. The grinding process may include a chemical mechanical polishing (CMP) process. Through the grinding process, the upper portion of the lower sealing layer 410 may be removed and the upper surface of the first semiconductor substrate 110 may be exposed. The exposed upper surface of the first semiconductor substrate 110 may be ground and an upper portion of the first semiconductor substrate 110 may be removed. The grinding process may be performed so that the end portions of the first through-vias 170 are exposed. For example, a portion of the first barrier layer 173 may be exposed through the grinding process. The exposed portion of the first barrier layer 173 may be further removed to expose an end portion 175E of the first conductive via 175. The end portion 175E of the first conductive via 175 may protrude from the upper surface 110a of the first semiconductor substrate 110. The upper surface of the remaining portion of first barrier layer 173 may be provided at a level that is the same as or similar to a level of the upper surface 110a of the first semiconductor substrate 110. The upper surface 110a of the first semiconductor substrate 110 may be provided at substantially the same level as a level of the upper surface 410a of the lower sealing layer 410.

Referring to FIGS. 5G and 5H, wherein FIG. 5H is an enlarged view of the region V of FIG. 5G, the insulating layer 420 may be formed on the upper surface 110a of the first semiconductor substrate 110 and the upper surface 410a of the lower sealing layer. The insulating layer 420 may be formed at the wafer level. The insulating layer 420 may include the first layer 421, the second layer 422, and the third layer 423. Each of the first layer 421, the second layer 422, and the third layer 423 may be formed through a deposition process. The first layer 421 may be formed to conformally cover the upper surface 410a of the lower sealing layer 410, the upper surface 110a of the first semiconductor substrate 110, the upper surface of the first barrier layer 173, and the end portion 175E of the first conductive via 175 that is exposed. The second layer 422 may be formed to conformally cover the first layer 421 on the upper surface 410a of the lower sealing layer 410, the upper surface 110a of the first semiconductor substrate 110, and the end portion 175E of the first conductive via 175 that is exposed. Thereafter, a portion of the second layer 422 and a portion of the first layer 421 may be removed to expose the end portion 175E of the first conductive via 175. The third layer 423 may be formed on the second layer 422. The first upper pad 160 may be formed within the third layer 423 and on the upper surface of the first conductive via 175 to connect to the first conductive via 175. Forming the first upper pad 160 may include forming the barrier pad 163 and forming the metal pad 165. The first upper pad 160 may not extend to the upper surface of the insulating layer 420. The upper surface of the first upper pad 160 may be provided at a level that is the same as or similar to a level of the upper surface of the insulating layer 420, but is not limited thereto. After the first upper pads 160 are formed, the thickness T (see FIG. 1A) of the first semiconductor chip 100 may be about 7 μm to about 60 μm.

Referring to FIG. 5I, a plurality of second semiconductor chips 200 may be prepared. The second semiconductor chips 200 may be disposed on the first semiconductor chips 100, respectively. The second semiconductor chips 200 may be directly bonded to the corresponding one of the first semiconductor chips 100 through a hybrid bonding process. For example, directly bonding the second semiconductor chips 200 to the first semiconductor chips 100 may include applying heat to the first semiconductor chips 100 and the second semiconductor chips 200.

The arrangement of the second semiconductor chips 200 may be repeated to form a plurality of stacks of the second semiconductor chips 200. By performing a hybrid bonding process, vertically adjacent ones of the second semiconductor chips 200 may be directly bonded to each other.

Third semiconductor chips 300 may be prepared. The third semiconductor chips 300 may include the third semiconductor substrate 310, the third integrated circuits 315, the third lower insulating layer 321, the third lower pad, and the third interconnection patterns 330 as described in the examples of FIGS. 1A and 1E but may not include third through-vias, third upper pads, and a third upper insulating layer.

The third semiconductor chips 300 may be disposed on the uppermost ones of the second semiconductor chips 200, and the third semiconductor chips 300 may be directly bonded to the uppermost ones of the second semiconductor chips 200. Direct bonding between the uppermost ones of the second semiconductor chips 200 and the third semiconductor chips 300 may be performed by a hybrid bonding process. Each of the third semiconductor chips 300 may be arranged to be laterally apart from each other.

Referring to FIG. 5J, the molding layer 430 may be formed on the upper surface of the base structure 500 and cover the sidewalls of the first semiconductor chips 100, the sidewalls of the second semiconductor chips 200, and the sidewalls of the third semiconductor chips 300. The molding layer 430 may further cover the upper surfaces 300a of the third semiconductor chips 300. Each of the upper surfaces 300a of the third semiconductor chips 300 may be the upper surface of a corresponding one of the third semiconductor substrates 310. Forming the molding layer 430 may be performed at the wafer level. Thereafter, a grinding process may be performed on the upper surface of the molding layer 430 to expose the upper surfaces 300a of the third semiconductor chips 300. After the grinding process, the upper surfaces 300a of the third semiconductor chips 300 may be disposed at substantially the same level as a level of the upper surface 430a of the molding layer 430. The grinding process may include a CMP process.

Referring to FIG. 5K, a carrier substrate 990 may be provided on the upper surfaces 300a of the third semiconductor chips 300 and the upper surface 430a of the molding layer 430. A carrier adhesive layer 980 may be formed between the carrier substrate 990 and the third semiconductor chips 300 and between the carrier substrate 990 and the molding layer 430. The carrier substrate 990 may be attached to the third semiconductor chips 300 and the molding layer 430 by the carrier adhesive layer 980. The carrier substrate 990 may be a temporary substrate or a support substrate. The carrier substrate 990 may support a wafer package. The wafer package may include the base structure 500, the first semiconductor chips 100, the second semiconductor chips 200, the third semiconductor chips 300, the lower sealing layer 410, the insulating layer 420, and the molding layer 430.

Referring to FIG. 5L, the wafer package and the carrier substrate 990 may be turned over so that the base structure 500 faces upwardly.

Referring to FIG. 5M, a grinding process may be performed on the base structure 500 to thin the base substrate 510. The lower surface of the conductive via 570 may be exposed through the grinding process. The lower surface of the conductive via 570 may be coplanar with the lower surface of the base substrate 510. The conductive via 570 may be one of a plurality of conductive vias 570. The grinding process may include a CMP process. The lower surface of the base structure 500 may include the lower surfaces of the conductive vias 570 and the lower surface of the base substrate 510.

Referring to FIG. 5N, the redistribution layer 600 may be formed on the lower surface of the base structure 500. Forming the redistribution layer 600 may include forming the organic insulating layers 610 through a coating process, forming the redistribution patterns 630 through a first plating process, and forming the redistribution pads 650 through a second plating process. The redistribution layer 600 may be manufactured by a chip first process but is not limited thereto. The solder ball terminals 700 may be formed on the lower surface of the redistribution layer 600 and electrically connected to the redistribution pads 650.

Referring to FIG. 5O, the wafer package and the carrier substrate 990 may be turned over so that the solder ball terminals 700 face downwardly.

Referring to FIG. 5P, the carrier substrate 990 and the carrier adhesive layer 980 may be removed to expose the upper surfaces of the third semiconductor chips 300 and the upper surface of the molding layer 430.

A sawing process may be performed on the molding layer 430, the insulating layer 420, the lower sealing layer 410, the base structure 500, and the redistribution layer 600 to cut the molding layer 430, the insulating layer 420, the lower sealing layer 410, the base structure 500, and the redistribution layer 600 as indicated by the dashed lines. Accordingly, the semiconductor packages 10 may be manufactured. The semiconductor packages 10 may be separated from each other by the sawing process. Each of the semiconductor packages 10 may be the same as the semiconductor package 10 described in the example of FIG. 1A. For example, each of the semiconductor packages 10 may include the redistribution layer 600, the base structure 500, the first semiconductor chip 100, the second semiconductor chips 200, the third semiconductor chip 300, the solder ball terminals 700, the lower sealing layer 410, the insulating layer 420, and the molding layer 430.

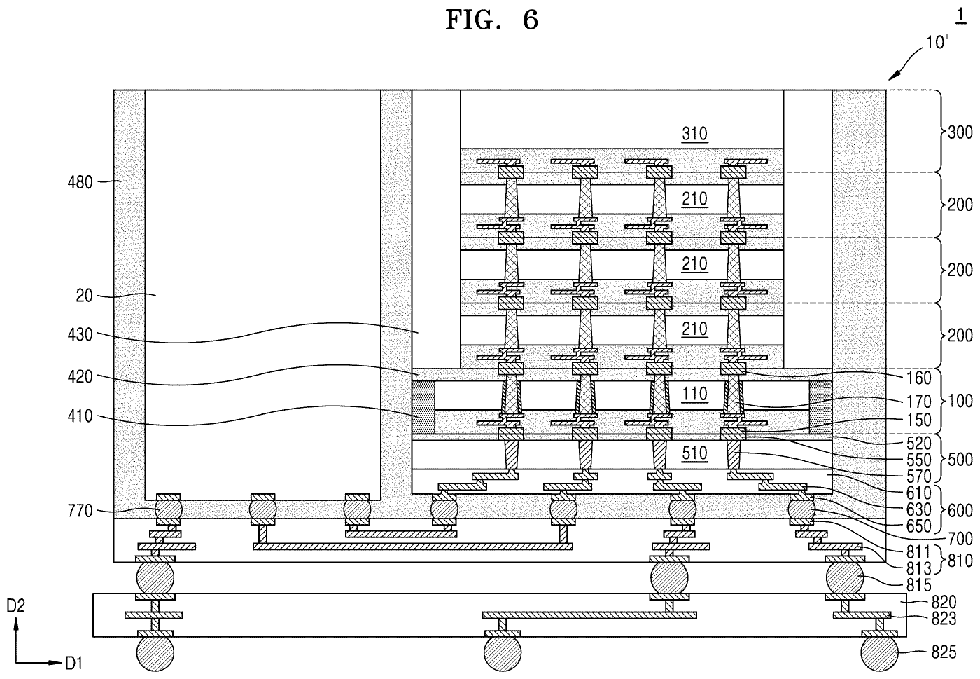

FIG. 6 is a diagram illustrating a semiconductor package 1 according to embodiments.

Referring to FIG. 6, the semiconductor package 1 may include solder balls 825, a package substrate 820, interposer solder balls 815, an interposer substrate 810, a semiconductor device 20, and a chip stack package 10′.

The package substrate 820 may include substrate interconnections 823. For example, a printed circuit board may be used as the package substrate 820. The substrate interconnections 823 may be provided within the package substrate 820. Being electrically connected to the package substrate 820 may refer to being electrically connected to at least one from among the substrate interconnections 823. The substrate interconnections 823 may include metal, such as copper, aluminum, tungsten, and/or titanium.

The solder balls 825 may be provided on the lower surface of the package substrate 820 and may be electrically connected to the substrate interconnections 823. External electrical signals may be transmitted to the solder balls 825. The solder balls 825 may include a solder material.

An interposer substrate 810 may be provided on the package substrate 820. The interposer substrate 810 may include upper interposer pads 811 and interposer interconnections 813. The upper interposer pads 811 may be disposed at (e.g., in or on) an upper surface of the interposer substrate 810. The upper interposer pads 811 may include metal. The interposer interconnections 813 may be provided within the interposer substrate 810 and may be electrically connected to the upper interposer pads 811. Being electrically connected to the interposer substrate 810 may refer to being electrically connected to at least one of the interposer interconnections 813. The interposer interconnections 813 may include metal, such as copper, aluminum, tungsten, and/or titanium.

The interposer solder balls 815 may be located between the package substrate 820 and the interposer substrate 810 and electrically connected to the package substrate 820 and the interposer substrate 810. A pitch of the interposer solder balls 815 may be smaller than a pitch of the solder balls 825. The interposer solder balls 815 may include a solder material.

The chip stack package 10′ may be disposed on an upper surface of the interposer substrate 810. The semiconductor package 10 described in the example of FIG. 1A may be used as the chip stack package 10′. For example, the chip stack package 10′ may include the redistribution layer 600, the base structure 500, the first semiconductor chip 100, the second semiconductor chips 200, the third semiconductor chip 300, the solder ball terminals 700, the lower sealing layer 410, the insulating layer 420, and the molding layer 430. Alternatively, the semiconductor package 10A of FIG. 2, the semiconductor package 10B of FIG. 3, or the semiconductor package 10C of FIG. 4 may be used as the chip stack package 10′.

The solder ball terminals 700 may be disposed on the upper interposer pads 811 and electrically connected to the upper interposer pads 811. For example, the solder ball terminals 700 may be bonded to the upper surfaces of the corresponding ones of the upper interposer pads 811. A pitch of the solder ball terminals 700 may be smaller than a pitch of the interposer solder balls 815.

The semiconductor device 20 may be provided on the interposer substrate 810 and may be laterally apart from the chip stack package 10′. The semiconductor device 20 may include a graphics processing unit (GPU) or a central processing unit (CPU).

The semiconductor device 20 may include integrated circuits and chip pads. The integrated circuits may be provided within the semiconductor device 20. The chip pads may be provided at a lower surface of the semiconductor device 20 and may be electrically connected to the integrated circuits of the semiconductor device 20.

Lower bumps 770 may be located between the interposer substrate 810 and the semiconductor device 20. For example, the lower bumps 770 may be connected to the chip pad of the semiconductor device 20 and the corresponding ones of the upper interposer pads 811. The lower bumps 770 may include a solder material. A pitch of the lower bumps 770 may be smaller than a pitch of the interposer solder balls 815. The semiconductor device 20 may be electrically connected to the chip stack package 10′ or the solder balls 825 through the interposer substrate 810.

A molding pattern 480 may be disposed on an upper surface of the interposer substrate 810 and cover sidewalls of the chip stack package 10′ and sidewalls of the semiconductor device 20. The molding pattern 480 may include a polymer, such as EMC. The molding pattern 480 may have insulating properties.

According to embodiments, the semiconductor package 1 may include two or more chip stack packages 10′. In this case, the semiconductor device 20 may be located between the chip stack packages 10′.

According to embodiments of the present disclosure, first chip-level semiconductor chips that have passed the test may be used in the manufacturing process of the semiconductor package. Accordingly, the efficiency of the manufacturing process of the semiconductor package may be improved.

The semiconductor package may have high capacity and high performance characteristics. Because the first semiconductor chip is directly bonded to the base structure, the semiconductor package may be miniaturized.

While non-limiting example embodiments of the present disclosure have been particularly shown and described with reference to the drawings, it will be understood that various changes in form and details may be made therein without departing from the spirit and scope of the present disclosure.

What is claimed is:

1. A semiconductor package comprising:
a base structure;
a first semiconductor chip on an upper surface of the base structure and directly bonded to the base structure;
a second semiconductor chip on the first semiconductor chip;
a lower sealing layer on the upper surface of the base structure and on a sidewall of the first semiconductor chip; and
a molding layer on an upper surface of the lower sealing layer and on a sidewall of the second semiconductor chip.

2. The semiconductor package of claim 1, further comprising:
an insulating layer between the first semiconductor chip and the second semiconductor chip and extending between the lower sealing layer and the molding layer.

3. The semiconductor package of claim 2, wherein the first semiconductor chip comprises:
a first semiconductor substrate;
a first through-via within the first semiconductor substrate; and
a first upper pad on an upper surface of the first through-via,
wherein the first through-via extends into the insulating layer, and
wherein the insulating layer is on a side surface of the first upper pad.

4. The semiconductor package of claim 3, wherein
the upper surface of the lower sealing layer is coplanar with an upper surface of the first semiconductor substrate.

5. The semiconductor package of claim 3, wherein the insulating layer is on an upper sidewall of the first through-via.

6. The semiconductor package of claim 2, wherein
an outer wall of the molding layer is coplanar with an outer wall of the insulating layer and an outer wall of the lower sealing layer.

7. The semiconductor package of claim 2, wherein
the second semiconductor chip comprises a lower insulating layer that defines at least a part of a lower surface of the second semiconductor chip, and
the insulating layer is directly bonded to a lower surface of the lower insulating layer.

8. The semiconductor package of claim 1, wherein the base structure comprises:
a base substrate;
a conductive via within the base substrate;
a base insulating layer on the base substrate; and
a conductive pad on the conductive via and within the base insulating layer, wherein the first semiconductor chip comprises a first lower pad at a lower surface of the first semiconductor chip, and
wherein the conductive pad is directly bonded to the first lower pad.

9. The semiconductor package of claim 8, further comprising:
a redistribution layer on a lower surface of the base structure,
wherein the redistribution layer comprises:
an organic insulating layer in direct contact with a lower surface of the base substrate;
a redistribution pattern within the organic insulating layer; and
a seed pattern on the redistribution pattern and directly contacting the conductive via.

10. The semiconductor package of claim 1, wherein the base structure does not include any integrated circuits.

11. A semiconductor package comprising:
a base structure;
a first semiconductor chip on an upper surface of the base structure and comprising a first substrate, a first through-via, and a first upper pad;
a lower sealing layer on the upper surface of the base structure and on a sidewall of the first semiconductor chip; and
an insulating layer on the first substrate and on a side surface of the first upper pad,
wherein the insulating layer extends to an upper surface of the lower sealing layer.

12. The semiconductor package of claim 11, further comprising:
second semiconductor chips stacked on the first semiconductor chip; and
a molding layer on the insulating layer and on sidewalls of the second semiconductor chips.

13. The semiconductor package of claim 11, wherein
the upper surface of the lower sealing layer is coplanar with an upper surface of the first substrate.

14. The semiconductor package of claim 11, wherein
the base structure comprises a base insulating layer that defines at least a part of an upper surface of the base structure,
the first semiconductor chip further comprises a first lower insulating layer that defines at least a part of a lower surface of the first semiconductor chip, and
the first lower insulating layer is directly bonded to the base insulating layer.

15. The semiconductor package of claim 11, wherein the insulating layer comprises:
a first layer on an upper surface of the lower sealing layer, on an upper surface of the first substrate, and on an upper sidewall of the first through-via;
a second layer on the first layer; and
a third layer on the second layer and on a side surface of the first upper pad;
wherein the second layer comprises an insulating material different from insulating materials of the first layer and the third layer.

16. The semiconductor package of claim 11, wherein
an outer wall of the insulating layer is coplanar with an outer wall of the lower sealing layer.

17. A semiconductor package comprising:
a base structure comprising a base substrate, a conductive via within the base substrate, a base insulating layer on the base substrate, and a conductive pad within the base insulating layer;
a redistribution layer on a lower surface of the base structure;
a solder ball terminal on a lower surface of the redistribution layer and electrically connected to the conductive via through the redistribution layer;
a first semiconductor chip on an upper surface of the base structure and comprising a first substrate, a first lower insulating layer on a lower surface of the first substrate, a first lower pad within the first lower insulating layer, a first through-via passing through the first substrate, and a first upper pad electrically connected to the first through-via;
a plurality of second semiconductor chips stacked on the first semiconductor chip, each of the plurality of second semiconductor chips comprising a second substrate, a second lower insulating layer, a second lower pad, a second through-via, a second upper insulating layer, and a second upper pad;
a lower sealing layer on the upper surface of the base structure and on a sidewall of the first semiconductor chip;
a molding layer on the lower sealing layer and on sidewalls of the plurality of second semiconductor chips; and
an insulating layer between the lower sealing layer and the molding layer and between the first semiconductor chip and a lowermost second semiconductor chip among the plurality of second semiconductor chips,
wherein the insulating layer is on a side surface of the first upper pad of the first semiconductor chip, and
wherein the first semiconductor chip is directly bonded to the base structure.

18. The semiconductor package of claim 17, wherein
an upper surface of the lower sealing layer is at a same level as an upper surface of the first substrate, and
an outer wall of the insulating layer is coplanar with an outer wall of the lower sealing layer.

19. The semiconductor package of claim 17, wherein
the first lower pad is directly bonded to the conductive pad, and
the first lower insulating layer is directly bonded to the base insulating layer.

20. The semiconductor package of claim 17, wherein
the second lower pad of the lowermost second semiconductor chip is directly bonded to the first upper pad,
the second lower insulating layer of the lowermost second semiconductor chip is directly bonded to the insulating layer, and
the first semiconductor chip has a thickness of 7 μm to 60 μm.
